(19) United States
(12) Patent Application Publication
(10) Pub. No.: US 2025/0393437 A1
(43) Pub. Date: Dec. 25, 2025

(54) DISPLAY DEVICE

(71) Applicant: LG Display Co., Ltd., Seoul (KR)

(72) Inventors: YongCheol KIM, Paju-si (KR); Mi-Na KIM, Paju-si (KR); Hyunsook JEON, Paju-si (KR)

(73) Assignee: LG Display Co., Ltd., Seoul (KR)

(21) Appl. No.: 19/242,754

(22) Filed: Jun. 18, 2025

(30) Foreign Application Priority Data
Jun. 20, 2024 (KR) 10-2024-0080542

(51) Int. Cl. H10K 59/65; H10H 29/80; H10H 29/852; H10K 59/80

(52) U.S. Cl. CPC H10K 59/65; H10H 29/8323; H10H 29/852; H10K 59/80517; H10K 59/80523; H10K 59/80524; H10K 59/873

(57) ABSTRACT

A display device can include a substrate having an optical area in which a detection sensor is disposed, a light emitting element disposed in the optical area, and a transmissive sensor disposed on the light emitting element so that the detection sensor can be disposed in the optical area without changing the density and structure of the subpixel of the display device.

### CROSS-REFERENCE TO RELATED APPLICATION

This application claims priority to Korean Patent Application No. 10-2024-0080542, filed in the Republic of Korea on Jun. 20, 2024, which is hereby expressly incorporated by reference into the present application in its entirety for all purposes as if fully set forth herein.

### BACKGROUND

### Technical Field

Example embodiments of the disclosure relate to a display device, and more particularly, for example, without limitation, to a display device having a sensor that senses light of a predefined wavelength band.

### Description of Related Art

As the information society develops, demand for display devices for displaying images is increasing in various forms. Various display devices, such as liquid crystal display devices, a plasma display device (PDP), a field emission display device (FED), a micro LED (Micro Light Emitting Diode) display device and organic light emitting display devices, are being utilized in recent years.

In addition to displaying images or videos, touch-based input functions are being developed to enable users to input information or commands more intuitively and conveniently.

Further, the display device can provide a detection function to perform a function depending on the light of the ambient environment. To that end, the display device should have various electronic devices (optical electronic devices), such as detection sensors and image sensors (cameras).

Since the electronic device receives light through the front of the display device, it can be installed where light reception is easy. In a display device according to a related art, the detection sensor can be exposed to the front or can be placed in a partial area with lower subpixel density.

The description provided in the discussion of the related art section should not be assumed to be prior art merely because it is mentioned in or associated with that section. The discussion of the related art section can include information that describes one or more aspects of the subject technology, and the description in this section does not limit the disclosure.

### BRIEF SUMMARY OF THE DISCLOSURE

The inventors of the disclosure realized that when the display device incorporates electronic components, such as detection sensors, that receive light through the front to perform predetermined functions, it can lead to reduced resolution in a partial area of the display device or impose limitations on the front-side design.

Example embodiments of the disclosure can provide a display device having a sensor that senses light of a predefined wavelength band (e.g., an infrared band).

Example embodiments of the disclosure can provide a display device having a transmissive sensor.

Example embodiments of the disclosure can provide a display device in which a sensor for receiving light is disposed in the display area of the display panel without affecting the arrangement of subpixels in the display area of the display panel.

Example embodiments of the disclosure can provide a display device in which a camera (also referred to as an image sensor) and a sensor overlap each other.

Purposes according to the disclosure are not limited to the above-mentioned purpose. Other purposes and advantages according to the disclosure that are not mentioned can be understood based on following descriptions, and can be more clearly understood based on embodiments according to the disclosure. Further, it will be easily understood that the purposes and advantages according to the disclosure can be realized using means shown in the claims or combinations thereof.

Example embodiments of the disclosure can provide a display device comprising a substrate including a display area including a plurality of emission areas and a non-display area outside the display area, a plurality of light emitting elements disposed on the substrate and respectively positioned in the plurality of emission areas, and a transmissive sensor layer disposed on the plurality of light emitting elements, wherein the plurality of light emitting elements include a first light emitting element, and the transmissive sensor layer is disposed on the first light emitting element and include a first transmissive sensor overlapping the first light emitting element.

Example embodiments of the disclosure can provide a display device comprising a substrate including a display area displaying an image, the display area including a normal area and an optical area, an optical sensor disposed under the substrate and disposed to overlap the optical area, and at least one transmissive sensor disposed on the substrate and overlapping the optical sensor.

Example embodiments of the disclosure can provide a display device can comprise a substrate including a display area; a plurality of light emitting elements disposed in the display area on the substrate and including a first light emitting element; and a transmissive sensor layer disposed on plurality of light emitting elements and comprising a plurality of transmissive sensors, wherein the first light emitting element and a first transmissive sensor of the plurality of transmissive sensors overlap each other.

Example embodiments of the disclosure can provide a display device can comprise a substrate including a display area displaying an image, the display area including a normal area and an optical area; an optical sensor disposed under the substrate and disposed to overlap the optical area; a plurality of light emitting elements disposed on the normal area and the optical area; at least one transmissive sensor disposed on the plurality of light emitting elements overlapping the optical sensor.

Example embodiments of the disclosure can provide a display device can comprise a substrate including a display area displaying an image, the display area including a normal area and an optical area; an optical sensor disposed under the substrate and disposed to overlap the optical area; at least one transmissive sensor overlapping the optical sensor, wherein the number of subpixels per unit area in the optical area is smaller than the number of subpixels per unit area in the normal area, and wherein the transmissive sensor is made of a transparent material.

According to example embodiments of the disclosure, there can be provided a display device having a sensor that senses light of a predefined wavelength band (e.g., an infrared band).

According to example embodiments of the disclosure, there can be provided a display device having a transmissive sensor through which light is transmitted.

According to example embodiments of the disclosure, as the sensor receiving light is disposed in the display area of the display panel, and the sensor is configured as a transmissive sensor, the arrangement of the subpixels in the display area of the display panel may not be affected.

According to example embodiments of the disclosure, as the sensor is configured as a transmissive sensor, the resolution and image quality of the display panel may not be deteriorated although the sensor receiving light is disposed in the display area of the display panel.

According to example embodiments of the disclosure, as the camera and the sensor are disposed to vertically overlap each other, the deterioration of the resolution and image quality of the display panel due to the camera and the sensor can be reduced although the camera and the sensor overlap the display area of the display panel.

According to example embodiments of the disclosure, as a sensor having a light-based detection function is configured as a transmissive sensor, the sensor can be disposed to overlap the light emitting element of at least one subpixel. Thus, it is possible to expand the area where the subpixels including light emitting elements are disposed. Therefore, there can be provided a display device with enhanced light emission efficiency to provide a light emission characteristic at reduced power.

It is to be understood that both the foregoing general description and the following detailed description of the disclosure are examples and explanatory and are intended to provide further explanation of the disclosure as claimed.

### BRIEF DESCRIPTION OF THE DRAWINGS

The above and other objects, features, and advantages of the disclosure will be more clearly understood from the following detailed description, taken in conjunction with the accompanying drawings, in which:

FIG. 1 is a view illustrating a configuration of a display device according to example embodiments of the disclosure;

FIG. 2 is a view illustrating a configuration of a system of a display device according to example embodiments of the disclosure;

FIG. 3 illustrates an equivalent circuit diagram illustrating a subpixel in a display panel according to example embodiments of the disclosure;

FIG. 4 is a view illustrating an arrangement of pixels in two areas included in a display area of a display panel according to example embodiments of the disclosure;

FIG. 5 is a view illustrating the respective cross sections of a normal area and an optical area included in a display area of a display panel according to example embodiments of the disclosure;

FIG. 6 is a view illustrating that a transmissive sensor is disposed in a display device according to example embodiments of the disclosure;

FIG. 7 is a view illustrating a cross-sectional structure in which a transmissive sensor is disposed in an emission area according to example embodiments of the disclosure;

FIG. 8 is a view illustrating that a transmissive sensor is disposed on each light emitting element of a normal area subpixel according to example embodiments of the disclosure;

FIG. 9 is a plan view illustrating an example of an area in which a transmissive sensor is disposed in a normal area of a display panel according to example embodiments of the disclosure;

FIG. 10 is a view illustrating that a transmissive sensor is disposed on a green light emitting element and a blue light emitting element of a normal area subpixel according to example embodiments of the disclosure;

FIG. 11 is a plan view illustrating an example of an area in which a transmissive sensor is disposed in a normal area of a display panel according to example embodiments of the disclosure;

FIG. 12 is a cross-sectional view taken along dashed line A-A′ of FIGS. 9 and 11;

FIG. 13 is a perspective view illustrating an optical area in which a light emitting element of a subpixel, a transmissive area, and a transmissive sensor are disposed according to example embodiments of the disclosure;

FIG. 14 is a view illustrating that a transmissive sensor is disposed on each light emitting element of a transmissive area subpixel according to example embodiments of the disclosure;

FIG. 15 is a plan view illustrating an optical area in which a light emitting element and a transmissive area are disposed according to example embodiments of the disclosure;

FIG. 16 is a cross-sectional view taken along dashed line B-B′ of FIGS. 13 and 15 in an optical area in which a subpixel, a transmissive area, and a transmissive sensor are disposed according to example embodiments of the disclosure;

FIGS. 17, 18, 19, and 20 are views illustrating a process of disposing a transmissive sensor on an optical area of a display panel according to example embodiments of the disclosure; and

FIG. 21 is a view illustrating a configuration of a transmissive sensor detection circuit according to example embodiments of the disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Reference will now be made in detail to embodiments of the disclosure, examples of which can be illustrated in the accompanying drawings. The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations can be selected only for convenience of writing the specification and can be thus different from those used in actual products.

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description can make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the disclosure, these elements should not be interpreted to be limited by these terms as they are not used to define a particular order or precedence. Each of these terms is not used to define essence, order, sequence, or number of elements etc., but is used merely to distinguish the corresponding element from other elements. For example, a first element could be termed a second element, and, similarly, a second element could be termed a first element, without departing from the scope of the disclosure.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may” and vice versa. Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

The features of the various embodiments of the disclosure can be partially or entirely combined with each other, and can be technically associated with each other or operate with each other. The embodiments can be implemented independently of each other and can be implemented together in an association relationship.

Hereinafter, various example embodiments of the disclosure are described in detail with reference to the accompanying drawings. All the components of each display device according to all embodiments of the disclosure are operatively coupled and configured. The scales of the components shown in the drawings have different scales from the actual ones for convenience of explanation, and thus are not limited to the scales shown in the drawings.

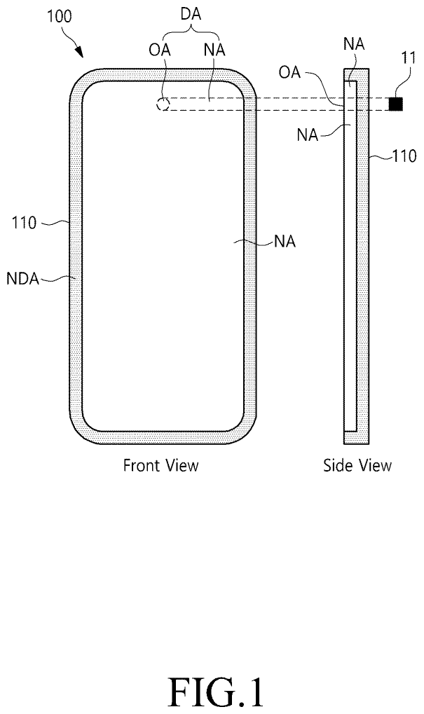

FIG. 1 is a view illustrating a configuration of a display device 100 according to example embodiments of the disclosure.

Referring to FIG. 1, the display device 100, according to example embodiments of the disclosure can include a display panel 110 for displaying an image and an optical electronic device 11.

The display panel 110 can include a display area DA in which images are displayed and a non-display area NDA in which no image is displayed.

A plurality of subpixels can be disposed in the display area DA, and various signal lines for driving the plurality of subpixels can be disposed in the display area DA.

The non-display area NDA can be an area outside the display area DA. In the non-display area NDA, various signal lines can be disposed, and various driving circuits can be connected thereto. The non-display area NDA can be bent to be invisible from the front or can be covered by a case. The non-display area NDA is also referred to as an edge or a bezel area.

In the display device 100 according to example embodiments of the disclosure, an optical electronic device 11 is an electronic component positioned under the display panel 110 (opposite to the viewing surface).

In the display device 100, one or more optical electronic devices 11 can be prepared independently of, and installed in, the display panel 110, and be located under, or in a lower portion of, the display panel 110 (an opposite side of a viewing surface thereof), without being limited thereto.

Light can enter the front surface (viewing surface) of the display panel 110 and pass through the display panel 110 to be transferred to the optical electronic device 11 positioned under the display panel 110 (opposite to the viewing surface).

The optical electronic device 11 can be a device that receives the light transmitted through the display panel 110 and performs a predetermined function according to the received light. For example, the optical electronic device 11 can include one or more of the following: a capturing device such as a camera (image sensor) and/or the like; or a sensor.

For example, the sensor can be a proximity sensor, an illuminance sensor, an infrared sensor, and/or the like. For example, the camera can be a camera lens, or a unit including at least one of the camera lens and the image sensor, and the sensor can be an infrared sensor capable of detecting infrared light.

In the display panel 110 according to example embodiments of the disclosure, the display area DA can include a normal area NA and an optical area OA.

The optical area OA can be an area overlapping the optical electronic device 11.

According to the example of FIG. 1, the display area DA can include a normal area NA and an optical area OA. Here, at least a portion of the optical area OA can overlap the optical electronic device 11.

However, although the optical area OA of FIG. 1 is illustrated as having a circular structure, the shape of the optical area OA according to example embodiments of the disclosure is not limited thereto.

For example, the optical area OA can be octagonal, or be formed into various polygonal shapes.

Alternatively, two or more optical areas OA can be included. In this case, an optical electronic device 11 can be disposed in each of two or more optical areas OA. For example, the first optical area is an area overlapping with the first optical electronic device, and the second optical area is an area overlapping with the second optical electronic device.

Further, the optical area OA should have both an image display structure and a light transmission structure. In other words, since the optical area OA is a partial area of the display area DA, subpixels for image display should be disposed in the optical area OA. Further, a light transmission structure for transmitting light to the optical electronic device 11 should be formed in the optical area OA.

The optical electronic device 11 is a device that requires light reception, but is positioned behind (below, opposite to the viewing surface) the display panel 110 to receive the light transmitted through the display panel 110.

The optical electronic device 11 is not exposed on the front surface (viewing surface) of the display panel 110. Therefore, when the user looks at the front surface of the display device 100, the optical electronic device 11 is not visible to the user.

For example, the optical electronic device 11 can be a camera.

In the following, for convenience of description, it is exemplified that the optical electronic device 11 is a camera. The camera can be a camera lens or an image sensor.

If the optical electronic device 11 is a camera, the camera can be a front camera that is positioned behind (below) the display panel 110 but captures forward of the display panel 110. The camera can be, for example, a camera lens, an image sensor, or a unit including at least one of the camera lens and the image sensor. Accordingly, the user can take a photograph through the camera invisible to the viewing surface while viewing the viewing surface of the display panel 110. It should be, however, understood that the scope of the disclosure includes embodiments where the optical electronic device 11 is the sensor.

The normal area NA and the optical area OA included in the display area DA are areas that can display images, but the normal area NA is an area that does not require a light transmission structure to be formed, and the optical area OA is an area that requires a light transmission structure to be formed.

Accordingly, the optical area OA should have a transmittance higher than or equal to a certain level, and the normal area NA can have no light transmittance or a lower transmittance less than the certain level.

For example, the optical area OA and the normal area NA can have different resolutions, subpixel placement structures, numbers of subpixels per unit area, electrode structures, line structures, electrode placement structures, or line placement structures.

For example, the number of subpixels per unit area in the optical area OA can be smaller than the number of subpixels per unit area in the normal area NA. In other words, the resolution of the optical area OA can be lower than the resolution of the normal area NA. For example, the number of subpixels per unit area can be the unit for measuring the resolution, and can also be referred to as pixels per inch (PPI), which means the number of pixels in one inch.

For example, the number of subpixels per unit area in the optical area OA can be smaller than the number of subpixels per unit area in the normal area NA.

The optical area OA can have various shapes, such as a circle, an ellipse, a quadrangle, a hexagon, or an octagon.

An example in which the optical area OA is circular is described below for convenience of description. It should be, however, understood that the scope of the disclosure includes examples where the optical area OA has a shape other than a circular shape, such as an ellipse, a quadrangle, a hexagon, an octagon or the like, without being limited thereto.

Accordingly, the display device 100, according to example embodiments of the disclosure does not require a notch or a hole for the optical electronic device 11 to be formed in the display panel 110, thereby preventing a reduction in the display area DA.

Thus, as there is no need to form a notch or a hole for exposure of the optical electronic device 11 in the display panel 110, the size of the bezel area can be reduced, and design restrictions can be freed, thereby increasing the degree of freedom in design.

In the display device 100 according to example embodiments of the disclosure, although the optical electronic device 11 is positioned to be hidden behind the display panel 110, the optical electronic device 11 should be able to normally perform predetermined functions by normally receiving light.

Further, in the display device 100 according to example embodiments of the disclosure, although the optical electronic device 11 is positioned to be hidden behind the display panel 110 and is positioned to overlap the display area DA, the optical area OA overlapping the optical electronic device 11 in the display area DA should be capable of normal image display.

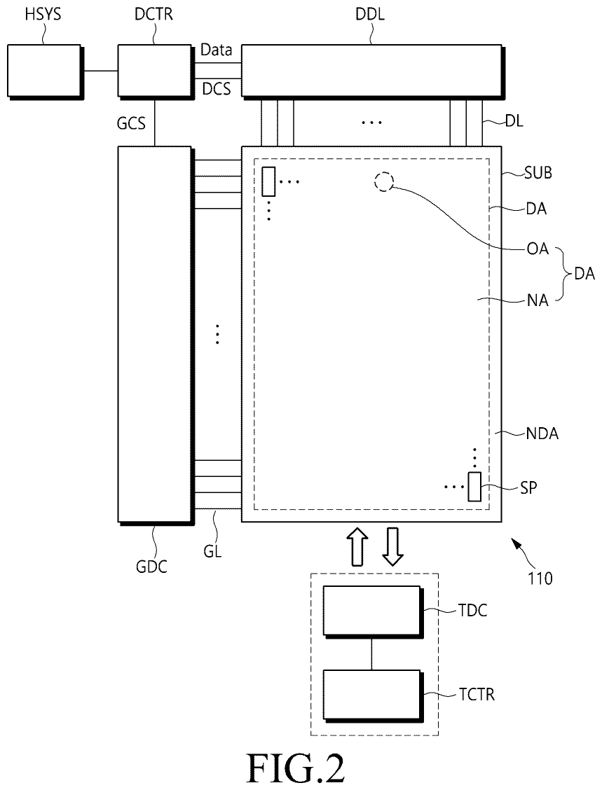

FIG. 2 is a view illustrating a system configuration of a display device 100 according to example embodiments of the disclosure.

Referring to FIG. 2, a display device 100 can include a display panel 110 and display driving circuits, as components for displaying images. The display panel 110 can correspond to the display panel 110 of FIG. 1.

The display driving circuits are circuits for driving the display panel 110 and can include, but is not limited to, a data driving circuit DDC, a gate driving circuit GDC, and a display controller DCTR, and other circuit components.

The display panel 110 can include a display area DA in which images are displayed and a non-display area NDA in which no image is displayed. The non-display area NDA can be an outer area of the display area DA and be referred to as an edge area or a bezel area. The whole or part of the non-display area NDA can be an area visible from the front surface of the display device 100 or an area that is bent and not visible from the front surface of the display device 100 or an area that is covered by a case or housing of the display device 100.

The display panel 110 can include a substrate SUB and a plurality of subpixels SP disposed on the substrate SUB. The display panel 110 can further include various types of signal lines to drive the plurality of subpixels SP.

The display device 100 according to example embodiments of the disclosure can be a liquid crystal display device (LCD), a plasma display device (PDP), a field emission display device (FED), or the like, or a self-emission display device in which the display panel 110 emits light by itself, such as an organic light-emitting display device (OLED), and a micro LED (Micro Light Emitting Diode) display device. When the display device 100 according to the embodiments of the disclosure is a self-emission display device, each of the plurality of subpixels SP can include a light emitting element.

For example, the display device 100 according to example embodiments of the disclosure can be an organic light emitting diode display in which the light emitting element is implemented as an organic light emitting diode (OLED). As another example, the display device 100 according to example embodiments of the disclosure can be an inorganic light emitting display device in which the light emitting element is implemented as an inorganic material-based light emitting diode. As another example, the display device 100 according to example embodiments of the disclosure can be a quantum dot display device in which the light emitting element is implemented as a quantum dot which is self-emission semiconductor crystal. However, the disclosure is not limited thereto.

The structure of each of the plurality of subpixels SP can vary according to the type of the display device 100. For example, when the display device 100 is a self-emission display device in which the subpixels SP emit light by themselves, each subpixel SP can include a light emitting element that emits light by itself, one or more transistors, and one or more capacitors.

For example, various types of signal lines can include a plurality of data lines DL transferring data signals (also referred to as data voltages or image signals) and a plurality of gate lines GL transferring gate signals (also referred to as scan signals), and the like.

The plurality of data lines DL and the plurality of gate lines GL can cross each other. Each of the plurality of data lines DL can be disposed to extend in a first direction. Each of the plurality of gate lines GL can be disposed to extend in a second direction different from the first direction.

Here, the first direction can be a column direction or vertical direction, and the second direction can be a row direction or horizontal direction, without being limited thereto. The first direction can be the row direction or horizontal direction, and the second direction can be the column direction or vertical direction.

The data driving circuit DDC is a circuit for driving the plurality of data lines DL, and can output data signals to the plurality of data lines DL. The gate driving circuit GDC is a circuit for driving the plurality of gate lines GL, and can output gate signals to the plurality of gate lines GL.

The display controller DCTR is a device for controlling the data driving circuit DDC and the gate driving circuit GDC and can control driving timings for the plurality of data lines DL and driving timings for the plurality of gate lines GL.

The display controller DCTR can supply a data driving control signal DCS to the data driving circuit DDC to control the data driving circuit DDC and can supply a gate driving control signal GCS to the gate driving circuit GDC to control the gate driving circuit GDC.

The display controller DCTR can receive input image data from the host system HSYS and supply image data Data to the data driving circuit DDC based on the input image data.

The data driving circuit DDC can supply data signals to the plurality of data lines DL according to the driving timing control of the display controller DCTR.

The data driving circuit DDC can receive digital image data Data from the display controller DCTR and can convert the received image data Data into analog data signals and output the analog data signals to the plurality of data lines DL.

The gate driving circuit GDC can supply gate signals to the plurality of gate lines GL according to the timing control of the display controller DCTR. The gate driving circuit GDC can receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

For example, the data driving circuit DDC can be connected with the display panel 110 by a tape automated bonding (TAB) method or connected to a conductive pad such as a bonding pad of the display panel 110 by a chip on glass (COG) or chip on panel (COP) method or can be connected with the display panel 110 by a chip on film (COF) method, without being limited thereto.

The gate driving circuit GDC can be connected with the display panel 110 by TAB method or connected to a conductive pad such as a bonding pad of the display panel 110 by a COG or COP method or can be connected with the display panel 110 according to a COF method. Alternatively, the gate driving circuit GDC can be formed in a gate in panel (GIP) type, in the non-display area NDA of the display panel 110. Alternatively, the gate driving circuit 230 can be disposed in the display area DA of the display panel 110. The gate driving circuit GDC can be disposed on the substrate or can be connected to the substrate. In other words, the gate driving circuit GDC that is of a GIP type can be disposed in the non-display area NDA of the substrate. The gate driving circuit GDC that is of a chip-on-glass (COG) type or chip-on-film (COF) type can be connected to the substrate.

Meanwhile, at least one of the data driving circuit DDC and the gate driving circuit GDC can be disposed in the display area DA of the display panel 110. For example, at least one of the data driving circuit DDC and the gate driving circuit GDC can be disposed not to overlap the subpixels SP or to overlap with all or some of the subpixels SP, or at least respective one or more portions of one or more subpixels SP, without being limited thereto.

The data driving circuit DDC can be located in, and/or electrically connected to, but not limited to, one side (e.g., an upper or lower side) of the display panel 110. Depending on the driving scheme or the panel design scheme, or the like, data driving circuits DDC can be located in, and/or electrically connected with, but not limited to, both the sides (e.g., both the upper and lower sides) of the display panel 110, or two or more of the four sides (e.g., the upper edge, the lower edge, a left edge, and a right edge) of the display panel 110.

The gate driving circuit GDC can be located in, and/or electrically connected to, but not limited to, one side (e.g., a left or right side) of the display panel 110. Depending on the driving scheme or the panel design scheme, gate driving circuits GDC can be connected with both the sides (e.g., both the left and right sides) of the display panel 110, or two or more of the four sides (e.g., an upper edge, a lower edge, the left edge, and the right edge) of the display panel 110.

The display controller DCTR can be implemented as a separate component from the data driving circuit DDC, or the display controller DCTR and the data driving circuit DDC can be integrated into an integrated circuit (IC) and thus implemented in an integrated circuit.

The display controller DCTR can be a timing controller used in typical display technology, a control device that can perform other control functions as well as the functions of the timing controller, or a control device other than the timing controller, or can be a circuit in the control device. The display controller DCTR can be implemented as various circuits or electronic components, such as an integrated circuit (IC), a field programmable gate array (FPGA), an application specific integrated circuit (ASIC), or a processor, and/or the like, without being limited thereto.

The display controller DCTR can be mounted on a printed circuit board or a flexible printed circuit and can be electrically connected with the data driving circuit DDC and the gate driving circuit GDC through the printed circuit board or the flexible printed circuit.

The display controller DCTR can transmit/receive signals to/from the data driving circuit DDC according to one or more predetermined interfaces. The interface can include, e.g., a low voltage differential signaling (LVDS) interface, an EPI interface, and a serial peripheral interface (SP). Similarly, the display controller DCTR can transmit signals to, and receive signals from, the gate driving circuit GDC via one or more predetermined interfaces.

To provide a touch sensing function as well as an image display function, the display device 100 according to example embodiments of the disclosure can include a touch sensor and a touch sensing circuit that senses the touch sensor to detect whether a touch occurs by a touch object, such as a finger or pen, or the position of the touch.

The touch sensing circuit can include a touch driving circuit TDC that drives and senses the touch sensor and generates and outputs touch sensing data and a touch controller TCTR that can detect an occurrence of a touch or the position of the touch (or touch coordinates) using touch sensing data, and one or more other components.

The touch sensor can include a plurality of touch electrodes. The touch sensor can further include a plurality of touch lines for electrically connecting the plurality of touch electrodes and the touch driving circuit TDC.

The touch sensor can be present in a touch panel form outside the display panel 110 or can be present inside the display panel 110. When the touch panel, in the form of a touch panel, exists outside the display panel 110, the touch panel is referred to as an external type. When the touch sensor is of the external type, the touch panel and the display panel 110 can be separately manufactured or can be combined during an assembly process. The external-type touch panel can include a touch panel substrate and a plurality of touch electrodes on the touch panel substrate.

When the touch sensor is present inside the display panel 110, the touch sensor can be formed on the substrate SUB, together with signal lines and electrodes related to display driving, during the manufacturing process of the display panel 110.

The touch driving circuit TDC can supply a touch driving signal to at least one of the plurality of touch electrodes and can sense at least one of the plurality of touch electrodes to generate touch sensing data.

The touch sensing circuit can perform touch sensing. The touch sensing circuit can perform touch sensing in a self-capacitance sensing scheme or a mutual-capacitance sensing scheme, without being limited thereto.

When the touch sensing circuit performs touch sensing in the self-capacitance sensing scheme, the touch sensing circuit can perform touch sensing based on capacitance between each touch electrode and the touch object (e.g., finger or pen).

According to the self-capacitance sensing scheme, each of the plurality of touch electrodes can serve both as a driving touch electrode and as a sensing touch electrode. The touch driving circuit TDC can drive all or some of the plurality of touch electrodes and sense all or some of the plurality of touch electrodes.

When the touch sensing circuit performs touch sensing in the mutual-capacitance sensing scheme, the touch sensing circuit can perform touch sensing based on capacitance between the touch electrodes.

According to the mutual-capacitance sensing scheme, the plurality of touch electrodes are divided into driving touch electrodes and sensing touch electrodes. The touch driving circuit TDC can drive the driving touch electrodes and sense the sensing touch electrodes.

The touch driving circuit TDC and the touch controller TCTR included in the touch sensing circuit can be implemented as separate devices or as a single device. The touch driving circuit TDC and the data driving circuit DDC can be implemented as separate devices or as a single device.

The display device 100 can further include a power supply circuit for supplying various types of power to the display driver integrated circuit and/or the touch sensing circuit.

The display device 100 according to example embodiments of the disclosure can be a mobile terminal, such as a notebook computer, a smart phone or a tablet, or a monitor or television (TV) in various sizes but, without limited thereto, can be a display in various types and various sizes capable of displaying information or images.

As described above, the display area DA in the display panel 110 can include the normal area NA and an optical area OA.

The normal area NA and the optical area OA are areas capable of displaying an image. However, the normal area NA is an area where a light transmission structure is not required to be formed, and the optical area OA is an area in which a light transmission structure is to be formed.

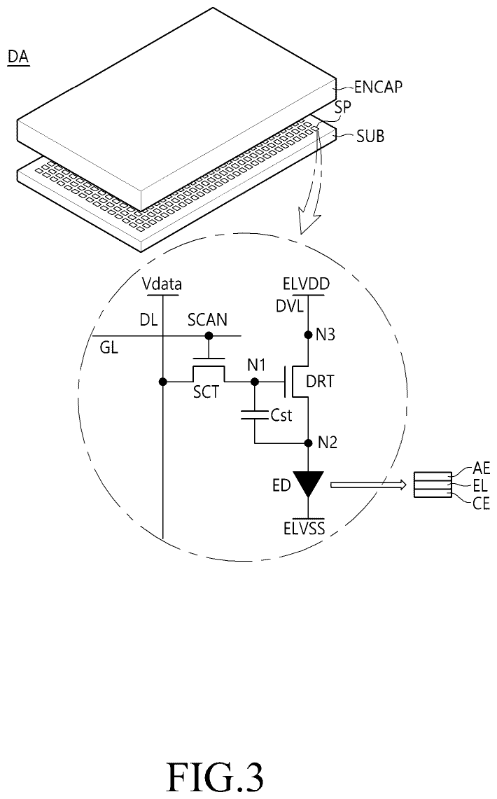

FIG. 3 is an equivalent circuit of a subpixel SP in a display panel 110 according to example embodiments of the disclosure.

Referring to FIG. 3, each subpixel SP disposed in the normal area NA and the optical area OA included in the display area DA of the display panel 110 can include an light emitting element ED, a driving transistor DRT for driving the light emitting element ED, a scan transistor SCT for transferring a data voltage Vdata to a first node N1 of the driving transistor DRT, and a storage capacitor Cst for maintaining a constant voltage during one frame, but embodiments of the disclosure are not limited thereto. More or less elements can be included.

The driving transistor DRT can include the first node N1 to which the data voltage can be applied, a second node N2 electrically connected with the light emitting element ED, and a third node N3 to which a driving voltage ELVDD is applied from a driving voltage line DVL. The first node N1 in the driving transistor DRT can be a gate node, the second node N2 can be a source node or a drain node, and the third node N3 can be the drain node or the source node. The source node and the drain node are not fixed and can be changed depending on a current direction and a voltage applied to the gate node.

The light emitting element ED can include a first electrode AE, a second electrode CE and a light emitting layer EL between the first electrode AE and a second electrode CE. The first electrode AE can be a pixel electrode disposed in each subpixel SP and be electrically connected to the second node N2 of the driving transistor DRT of each subpixel SP. The second electrode CE can be a common electrode commonly disposed in the plurality of subpixels SP, and a base voltage ELVSS can be applied thereto.

For example, the first electrode AE can be a pixel electrode, and the second electrode CE can be a common electrode. Conversely, the first electrode AE can be a common electrode, and the second electrode CE can be a pixel electrode. Hereinafter, for convenience of description, it is assumed that the first electrode AE is a pixel electrode and the second electrode CE is a common electrode.

When a driving current is supplied from the driving transistor DRT, electrons from the second electrode CE can be injected into the light emitting layer EL and holes from the first electrode AE can be injected into the light emitting layer EL, so that the light emitting element ED can allow fluorescent or phosphorescent materials to emit light through recombination of the electrons and the holes in the light emitting layer, thereby generating light of brightness proportional to a current value of the driving current.

For example, the light emitting element ED can be an organic light emitting diode (OLED), an inorganic light emitting diode, or a quantum dot light emitting element. In this case, when the light emitting element ED is an organic light emitting diode, the light emitting layer EL of the light emitting element ED can include an organic light emitting layer including an organic material.

The scan transistor SCT can be on/off controlled by a scan signal SCAN, which is a gate signal, applied via the gate line GL and be electrically connected between the first node N1 of the driving transistor DRT and the data line DL. When the scan transistor SCT is turned on, the data voltage Vdata applied through the data line DL can be transferred to one end of the storage capacitor Cst.

The storage capacitor Cst can be electrically connected between the first node N1 and second node N2 of the driving transistor DRT.

Each subpixel SP can have a 2T (transistor) 1C (capacitor) structure which includes two transistors DRT and SCT and one capacitor Cst as shown in FIG. 3 and, in some cases, each subpixel SP can further include one or more transistors or one or more capacitors. Various structures such as 4T2C, 5T2C, 6T1C, 6T2C, 7T1C and 7T2C, and so on can be also possible.

The capacitor Cst can be an external capacitor intentionally designed to be outside the driving transistor DRT, but not a parasite capacitor (e.g., Cgs or Cgd) which is an internal capacitor that can be present between the first node N1 and the second node N2 of the driving transistor DRT.

Each of the driving transistor DRT and the scan transistor SCT can be an n-type transistor or a p-type transistor.

Since the circuit elements (particularly, the light emitting element ED) in each subpixel SP are vulnerable to external moisture or oxygen, an encapsulation layer ENCAP can be disposed on the display panel 110 to prevent penetration of external moisture or oxygen into the circuit elements (particularly, the light emitting element ED). The encapsulation layer ENCAP can be disposed to cover the light emitting elements ED.

Meanwhile, as one method to increase the transmittance of the optical area OA, a pixel density differential design scheme can be applied as described above. According to the pixel density differential design scheme, the display panel 110 can be designed so that the number of subpixels per unit area of the optical area OA is smaller than the number of subpixels per unit area of the normal area NA.

However, in some cases, the pixel size differential design scheme can be applied as another method to increase the transmittance of the optical area OA. According to the pixel size differential design scheme, the display panel 110 can be designed so that the number of subpixels per unit area of the optical area OA is identical or similar to the number of subpixels per unit area of the normal area NA, and the size of each subpixel (i.e., the size of the emission area) disposed in the optical area OA is smaller than the size of each subpixel SP (i.e., the size of the emission area) disposed in the normal area NA.

Hereinafter, for convenience of description, it is assumed in the following description that, of the two schemes (pixel density differential design scheme and pixel size differential design scheme) for increasing the transmittance of the optical area OA, the pixel density differential design scheme is applied.

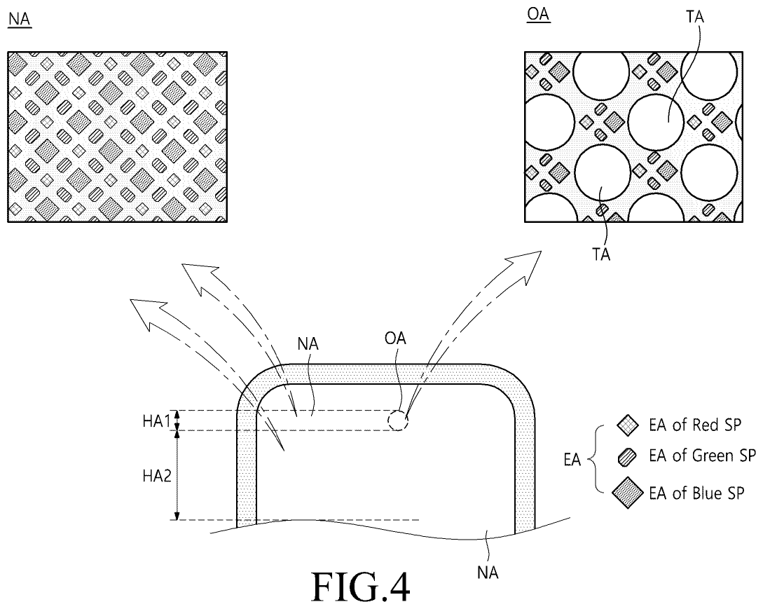

FIG. 4 is a view illustrating an arrangement of subpixels SP in two areas NA and OA included in a display area DA of a display panel 110 according to example embodiments of the disclosure.

Referring to FIG. 4, a plurality of subpixels SP can be disposed in each of the normal area NA and the optical area OA included in the display area DA.

As one example, the plurality of subpixels SP can include a first subpixel emitting light of a first color, a second subpixel emitting light of a second color, and a third subpixel emitting light of a third color.

For example, the plurality of subpixels SP can include a red subpixel Red SP emitting red light, a green subpixel Green SP emitting green light, and a blue subpixel Blue SP emitting blue light, without being limited thereto.

Accordingly, each of the normal area NA and the optical area OA can include emission areas EA of the red subpixels Red SP, emission areas EA of the green subpixels Green SP, and emission areas EA of the blue subpixels Blue SP.

The normal area NA may not include a light transmission structure, but can include light emission areas EA, such as emission areas EA of the red subpixels Red SP, emission areas EA of the green subpixels Green SP, and emission areas EA of the blue subpixels Blue SP.

However, the optical area OA should not only include the emission areas EA, but also include a light transmission structure, without being limited thereto.

Thus, the optical area OA can include emission areas EA and a transmissive area TA.

The emission areas EA and the transmissive area TA can be distinguished based on whether they can transmit light. In other words, the emission areas EA can be areas through which light cannot pass, and the transmissive area TA can be areas through which light can pass.

Further, the emission areas EA and the transmissive area TA can be distinguished depending on the presence or absence of a second electrode CE. For example, a second electrode CE may be formed in the emission areas EA, and a second electrode CE may not be formed in the transmissive area TA. A light shield layer can be formed in the emission areas EA, and a light shield layer may not be formed in the transmissive area TA.

Since the optical area OA includes the transmissive area TA, the optical area OA is an area through which light can be transmitted. The normal area NA may not include the transmissive area TA, the normal area NA is an area where light cannot be transmitted.

Further, in embodiments of the disclosure, the transmissive area TA can also be referred to as a transparent area, and the transmittance can also be referred to as transparency.

In embodiments of the disclosure, it is assumed that the optical area OA is positioned at the upper end of the display area DA of the display panel 110.

A horizontal display area in which the optical area OA is disposed is referred to as a first horizontal display area HA1, and a horizontal display area in which the optical area OA is not disposed is referred to as a second horizontal display area HA2. For example, the first horizontal display area HA1 can be disposed above the second horizontal display area HA2, without being limited thereto.

The first horizontal display area HA1 can include a normal area NA and an optical area OA. The second horizontal display area HA2 can include only the normal area NA.

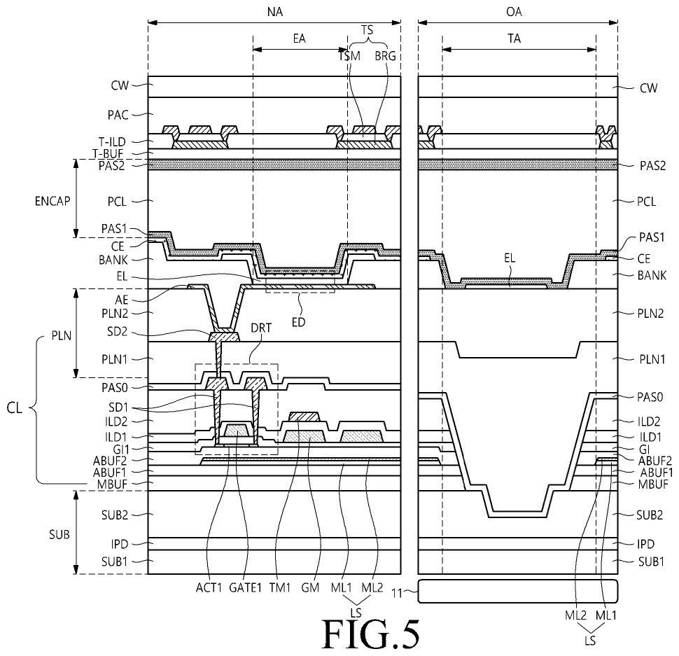

FIG. 5 is a view illustrating the respective cross sections of a normal area NA and an optical area OA included in a display area DA of a display panel 110 according to example embodiments of the disclosure.

Particularly, FIG. 5 illustrates cross-sectional views of the display panel 110 when the touch sensor TS is present inside the display panel 110, and illustrates cross-sectional views of the normal area NA and the optical area OA included in the display area DA.

Referring to FIG. 5, the stacked structure of the normal area NA is described. The emission area EA included in the optical area OA can have the same stacked structure as the emission area EA in the normal area NA.

The substrate SUB can include a first substrate SUB1, an interlayer insulation film IPD, and a second substrate SUB2. The interlayer insulation film IPD can be positioned between the first substrate SUB1 and the second substrate SUB2. By configuring the substrate SUB with the first substrate SUB1, the interlayer insulation film IPD and the second substrate SUB2, it is possible to prevent moisture penetration. For example, the first substrate SUB1 and the second substrate SUB2 can be polyimide (PI) substrates. The first substrate SUB1 can be referred to as a primary PI substrate, and the second substrate SUB2 can be referred to as a secondary PI substrate.

On the substrate SUB, various patterns ACT1, SD1, and GATE1 for forming a transistor, such as a driving transistor DRT, various insulation films MBUF, ABUF1, ABUF2, GI, ILD1, ILD2, and PAS0, and various metal patterns TM1, GM, ML1, and ML2 can be disposed.

A multi-buffer layer MBUF can be disposed on the second substrate SUB2. A first active buffer layer ABUF1 can be disposed on the multi-buffer layer MBUF.

A first metal layer ML1 and a second metal layer ML2 can be disposed on the first active buffer layer ABUF1. The first metal layer ML1 and the second metal layer ML2 can be a light shield layer LS for shielding light. For example, the first metal layer ML1 can be disposed on the first active buffer layer ABUF1, and the second metal layer ML2 can be disposed on the first metal layer ML1.

A second active buffer layer ABUF2 can be disposed on the first metal layer ML1 and the second metal layer ML2. A first active layer ACT1 of the driving transistor DRT can be disposed on the second active buffer layer ABUF2.

A first gate insulation film GI1 can be disposed to cover the first active layer ACT1. For example, the first gate insulation film GI1 can be disposed on the first active layer ACT1 and a portion of the second active buffer layer ABUF2.

A first gate electrode GATE1 of the driving transistor DRT can be disposed on the first gate insulation film GI1. In this case, in a position different from the position where the driving transistor DRT is formed, a gate material layer GM, together with the first gate electrode GATE1 of the driving transistor DRT, can be disposed on the first gate insulation film GI1.

The first interlayer insulation film ILD1 can be disposed to cover the first gate electrode GATE1 and the gate material layer GM. For example, the first interlayer insulation film ILD1 can be disposed on the first gate electrode GATE1, the gate material layer GM and a portion of the first gate insulation film GI1. A metal pattern TM1 can be disposed on the first interlayer insulation film ILD1. The metal pattern TM1 can be located in a position different from the position where the driving transistor DRT is formed. For example, the metal pattern TM1 can be disposed on the first interlayer insulation film ILD1. The second interlayer insulation film ILD2 can be disposed to cover the metal pattern TM1 on the first interlayer insulation film ILD1.

Two first source-drain electrode patterns SD1 can be disposed on the second interlayer insulation film ILD2. One of the two first source-drain electrode patterns SD1 is the source node of the driving transistor DRT, and the other is the drain node of the driving transistor DRT. The two first source-drain electrode patterns SD1 can be electrically connected with the two opposite sides of the first active layer ACT1 through the contact hole of the second interlayer insulation film ILD2, the first interlayer insulation film ILD1, and the first gate insulation film GI1.

A portion of the first active layer ACT1 overlapping the first gate electrode GATE1 is a channel area. One of the two first source-drain electrode patterns SD1 can be connected to one side of the channel area in the first active layer ACT1, and the other one of the two first source-drain electrode patterns SD1 can be connected to the other side of the channel area in the first active layer ACT1.

A passivation layer PAS0 is disposed to cover the two first source-drain electrode patterns SD1. For example, the passivation layer PAS0 can be disposed on the two first source-drain electrode patterns SD1 and a portion of the second interlayer insulation film ILD2. A planarization layer PLN can be disposed on the passivation layer PAS0. The planarization layer PLN can include a first planarization layer PLN1 and a second planarization layer PLN2, without being limited thereto.

The first planarization layer PLN1 can be disposed on the passivation layer PAS0.

A second source-drain electrode pattern SD2 can be disposed on the first planarization layer PLN1. The second source-drain electrode pattern SD2 can be connected with one of the two first source-drain electrode patterns SD1 (corresponding to the second node N2 of the driving transistor DRT in the subpixel SP of FIG. 3) through the contact hole of the first planarization layer PLN1.

The second planarization layer PLN2 can be disposed to cover the second source-drain electrode pattern SD2. For example, the second planarization layer PLN2 can be disposed on the second source-drain electrode pattern SD2 and a portion of the first planarization layer PLN1. A light emitting element ED can be disposed on the second planarization layer PLN2.

In the stacked structure of the light emitting element ED, the first electrode AE can be disposed on the second planarization layer PLN2. The first electrode AE can be electrically connected to the second source-drain electrode pattern SD2 through the contact hole of the second planarization layer PLN2.

The bank BANK can be disposed to cover a portion of the first electrode AE. A portion of the bank BANK corresponding to the light emitting area EA of the subpixel SP can be opened.

The bank BANK serves to define a subpixel. Thus, the bank BANK can be made of an insulating material containing a black material. The bank BANK can be made of, for example, a transparent carbon-based mixture. Specifically, the bank BANK can contain carbon black, but is not limited thereto. The bank BANK can also be made of a transparent insulating material.

A portion of the first electrode AE can be exposed through an opening (open portion) of the bank BANK. A light emitting layer EL can be positioned on a side surface of the bank BANK and the opening (open portion) of the bank BANK. The whole or part of the light emitting layer EL can be positioned between adjacent banks BANK.

In the opening of the bank BANK, the light emitting layer EL can contact the first electrode AE. A second electrode CE can be disposed on the light emitting layer EL. For example, the second electrode CE can be disposed on the light emitting layer El and the bank BANK.

The light emitting element ED can be formed by the first electrode AE, the light emitting layer EL, and the second electrode CE. The light emitting layer EL can include an organic film.

For example, the light emitting layer EL can include one or more of a hole injection layer (HIL), a hole transmitting layer (HTL), an electron transmitting layer (ETL) and an electron injection layer (EIL), but the disclosure is not limited thereto.

An encapsulation layer ENCAP can be disposed on the above-described light emitting element ED.

The encapsulation layer ENCAP can have a single-layer structure or a multi-layer structure. For example, as illustrated in FIG. 5, the encapsulation layer ENCAP can include a first encapsulation layer PAS1, a second encapsulation layer PCL, and a third encapsulation layer PAS2. For example, the second encapsulation layer PCL can be disposed between the first encapsulation layer PAS1 and the third encapsulation layer PAS2.

For example, the first encapsulation layer PAS1 and the third encapsulation layer PAS2 can be inorganic films, and the second encapsulation layer PCL can be an organic layer. Among the first encapsulation layer PAS1, the second encapsulation layer PCL, and the third encapsulation layer PAS2, the second encapsulation layer PCL can be the thickest and serve as a planarization layer, without being limited thereto.

The first encapsulation layer PAS1 can be disposed on the second electrode CE and be disposed closest to the light emitting element ED. The first encapsulation layer PAS1 can be formed of an inorganic insulating material capable of low-temperature deposition. For example, the first encapsulation layer PAS1 can be formed of silicon nitride (SiNx), silicon oxide (SiOx), silicon oxynitride (SiON), or aluminum oxide (Al₂O₃). Since the first encapsulation layer PAS1 is deposited in a low temperature atmosphere, the first encapsulation layer PAS1 can prevent damage to the light emitting layer EL including an organic material vulnerable to a high temperature atmosphere during the deposition process.

The second encapsulation layer PCL can have a smaller area than the first encapsulation layer PAS1. In this case, the second encapsulation layer PCL can be formed to expose two opposite ends of the first encapsulation layer PAS1. The second encapsulation layer PCL serves as a buffer for relieving stress between layers due to bending of the display device 100 and can also serve to enhance planarization performance. For example, the second encapsulation layer PCL can be an acrylic resin, an epoxy resin, polyimide, polyethylene, or silicon oxocarbon (SiOC) and be formed of an organic insulating material. For example, the second encapsulation layer PCL can be formed through an inkjet scheme.

The third encapsulation layer PAS2 can be formed on the substrate SUB, where the second encapsulation layer PCL is formed, to cover the respective upper surfaces and side surfaces of the second encapsulation layer PCL and the first encapsulation layer PAS1. The third encapsulation layer PAS2 can minimize or block penetration of external moisture or oxygen into the first encapsulation layer PAS1 and the second encapsulation layer PCL. For example, the third encapsulation layer PAS2 and the first encapsulation layer PAS1 can be inorganic encapsulation layer, and the second encapsulation layer PCL can be organic encapsulation layer. For example, the third encapsulation layer PAS2 is formed of an inorganic insulating material, such as silicon nitride (SiNx), silicon oxide (SiOx), silicon oxynitride (SiON), or aluminum oxide (Al₂O₃).

When the touch sensor TS is of a type embedded in the display panel 110, the touch sensor TS can be disposed on the encapsulation layer ENCAP. The touch sensor structure is described below in detail.

A touch buffer film T-BUF can be disposed on the encapsulation layer ENCAP. A touch sensor TS can be disposed on the touch buffer film T-BUF.

The touch sensor TS can include touch sensor metals TSM and a bridge metal BRG positioned on different layers. For example, the touch sensor metals TSM can be disposed on the bridge metal BRG, and the bridge metal BRG can be disposed on the touch buffer film T-BUF.

A touch interlayer insulation film T-ILD can be disposed between the touch sensor TS comprising the touch sensor metals TSM and the bridge metal BRG. The touch interlayer insulation film T-ILD can be disposed on the touch buffer film T-BUF.

For example, the touch sensor metals TSM can include a first touch sensor metal TSM, a second touch sensor metal TSM, and a third touch sensor metal TSM that are disposed adjacent to each other. The third touch sensor metal TSM is disposed between the first touch sensor metal TSM and the second touch sensor metal TSM and, when the first touch sensor metal TSM and the second touch sensor metal TSM are electrically connected to each other, the first touch sensor metal TSM and the second touch sensor metal TSM can be electrically connected to each other through the bridge metal BRG positioned on a different layer. The bridge metal BRG can be insulated from the third touch sensor metal TSM by the touch interlayer insulation film T-ILD.

When the touch sensor TS is formed on the display panel 110, moisture can be generated from the chemical solution (e.g., developer or etchant) used in the process. By disposing the touch sensor TS on the touch buffer film T-BUF, it is possible to prevent a chemical solution or moisture from penetrating into the light emitting layer EL including an organic material during the manufacturing process of the touch sensor TS. Thus, the touch buffer film T-BUF can prevent damage to the light emitting layer EL vulnerable to chemicals or moisture.

The touch buffer film T-BUF is formed of an organic insulation material with a low permittivity of 1 to 3 and formed at a low temperature which is not more than a predetermined temperature (e.g., 100° C.) to prevent damage to the light emitting layer EL containing the organic material vulnerable to high temperature. For example, the touch buffer film T-BUF can be formed of an acrylic-based, epoxy-based, or siloxane-based material. As the display device 100 is bent, the encapsulation layer ENCAP can be damaged, and the touch sensor metal positioned on the touch buffer film T-BUF can be broken. Even when the display device 100 is bent, the touch buffer film T-BUF formed of an organic insulating material and having planarization capability can prevent damage to the encapsulation layer ENCAP and/or breakage of the metals TSM and BRG constituting the touch sensor TS.

A protective 1 layer PAC can be disposed to cover the touch sensor TS on the encapsulation layer ENCAP to protect the touch sensor TS. The protective layer PAC can be an organic insulation film. For example, the protective layer PAC can be disposed on the touch sensor TS and the touch interlayer insulation film T-ILD.

The cover window CW can be disposed to cover the protective layer PAC. The cover window CW can serve to protect the display panel 110 from being broken by an external impact.

Next, a stacked structure for the optical area OA is described with reference to FIG. 5.

The emission area EA in the optical area OA can have the same stacked structure as the stacked structure of the normal area NA. Therefore, the stacked structure of the first transmissive area TA1 in the optical area OA is described below in detail.

The second electrode CE is disposed in the normal area NA and the emission area EA included in the optical area OA, but the second electrode CE may not be disposed in the transmissive area TA in the optical area OA. In other words, the transmissive area TA in the optical area OA can correspond to the opening of the second electrode CE.

Further, the light shield layer LS including at least one of the first metal layer ML1 and the second metal layer ML2 is disposed in the emission area EA included in the normal area NA, but the light shield layer LS may not be disposed in the transmissive area TA in the optical area OA. In other words, the transmissive area TA in the optical area OA can correspond to the opening of the light shield layer LS.

The substrate SUB and various insulation films MBUF, ABUF1, ABUF2, GI, ILD1, ILD2, PAS0, PLN (PLN1, PLN2), BANK, ENCAP (PAS1, PCL, PAS2), T-BUF, T-ILD, and PAC disposed in the emission area EA included in the normal area NA and the optical area OA can be equally disposed in the transmissive area TA in the optical area OA.

However, in the emission area EA included in the normal area NA and the optical area OA, a material layer (e.g., a metal material layer, a semiconductor layer, etc.) having electrical properties other than the insulating material may not be disposed in the transmissive area TA in the optical area OA.

For example, the metal material layers ML1, ML2, GATE1, GM, TM1, SD1, and SD2 related to the transistor and the first active layer ACT1 may not be disposed in the first transmissive area TA1.

Further, the first electrode AE and the second electrode CE included in the light emitting element ED may not be disposed in the first transmissive area TA1. However, the light emitting layer EL may or may not be disposed in the first transmissive area TA1.

Further, the touch sensor metal TSM and the bridge metal BRG included in the touch sensor TS may not be disposed in the transmissive area TA in the optical area OA.

Therefore, light transmittance of the transmissive area TA in the optical area OA can be provided by not disposing a material layer (e.g., a metal material layer, a semiconductor layer, etc.) having electrical characteristics in the optical area OA. Accordingly, the optical electronic device 11 can perform the corresponding function (e.g., image sensing) by receiving the light transmitted through the transmissive area TA.

Since the whole or part of the transmissive area TA in the optical area OA overlaps the optical electronic device 11, for normal operation of the optical electronic device 11, the transmittance of the transmissive area TA in the optical area OA needs to be further increased.

To this end, in the display panel 110 of the display device 100 according to example embodiments of the disclosure, the transmissive area TA in the optical area OA can have a transmission improvement structure (TIS).

The plurality of insulation films included in the display panel 110 can include buffer layers MBUF, ABUF1, and ABUF2 between the substrates SUB1 and SUB2 and the transistors DRT and SCT, a first planarization layer PLN1 and s second planarization layer PLN2 between the transistor DRT and the light emitting element, and an encapsulation layer ENCAP on the light emitting element ED.

The plurality of insulation films included in the display panel 110 can further include a touch buffer film T-BUF and a touch interlayer insulation film T-ILD on the encapsulation layer ENCAP.

The transmissive area TA in the optical area OA is a transmittance improvement structure (TIS), and can have a structure where the first planarization layer PLN1 and the passivation layer PAS0 are recessed in the lower direction.

Among the plurality of insulation films, the first planarization layer PLN1 can include at least one uneven portion (or recessed portion). Here, the first planarization layer PLN1 can be an organic insulation film.

When the first planarization layer PLN1 is recessed in the lower direction, the second planarization layer PLN2 can serve as a substantial planarization function. Meanwhile, the second planarization layer PLN2 can also be recessed in the lower direction. In this case, the second encapsulation layer PCL can serve as a substantial planarization layer.

The first planarization layer PLN1 and second planarization layer PLN2 can be formed of one or more materials of acrylic resin, epoxy resin, phenolic resin, polyamides resin, unsaturated polyesters resin, polyphenylene resin, polyphenylene sulfides resin, and benzocyclobutene, but embodiments are not limited thereto.

The first planarization layer PLN1 and the passivation layer PAS0 can be recessed in the lower direction, the recessed portions of the first planarization layer PLN1 and the passivation layer PAS0 can pass through the insulation films ILD2, IDL1, and GI for forming the transistor DRT and the buffer layers ABUF1, ABUF2, and MBUF disposed thereunder, and can come down to the upper portion of the second substrate SUB2.

The substrate SUB has a transmittance improvement structure (TIS) and can include at least one concave portion. For example, in the transmissive area TA, the upper surface of the second substrate SUB2 can be recessed or pierced in the lower direction.

The first encapsulation layer PAS1 and the second encapsulation layer PCL constituting the encapsulation layer ENCAP can also have a transmittance improvement structure (TIS) in the form of being recessed downward. Here, the second encapsulation layer PCL can be an organic insulation film.

The protective layer PAC can be disposed to cover the touch sensor TS on the encapsulation layer ENCAP to protect the touch sensor TS. The protective layer PAC can be an organic insulation film. For example, the protective layer PAC can be disposed on the touch sensor TS and the touch interlayer insulation film T-ILD.

The protective layer PAC can have at least one uneven portion as a transmittance improvement structure (TIS) at a portion overlapping the transmissive area TA. Here, the protective layer PAC can be an organic insulation film.

The cover window CW can be disposed to cover the protective layer PAC. The cover window CW can serve to protect the display panel 110 from being broken by an external impact.

The touch sensor TS can be formed of a mesh-type touch sensor metal TSM. When the touch sensor metal TSM is formed in a mesh type, a plurality of open areas can be present in the touch sensor metal TSM. Each of the plurality of open areas can correspond in position to the emission area EA of the subpixel SP.

The area of the touch sensor metal TSM per unit area in the optical area OA can be smaller than the area of the touch sensor metal TSM per unit area in the normal area NA so that the transmittance of the optical area OA is higher than that of the normal area.

A touch sensor TS can be disposed in the emission area EA in the optical area OA, and the touch sensor metal TSM and the bridge metal BRG included in a touch sensor TS may not be disposed in the transmissive area TA in the optical area OA.

In order to drive the light emitting element ED, the planarization layer PLN, the driving transistor DRT, various patterns ACT1, SD1, and GATE1, various insulation films MBUF, ABUF1, ABUF2, GI, ILD1, ILD2, and PAS0 and various metal patterns TM1, GM, ML1, and ML2 can be collectively referred to as a circuit layer CL.

Meanwhile, the display panel 110 can include two or more optical areas OA. When the optical electronic device 11, which is a camera, is disposed in one optical area OA, a detection sensor such as a proximity sensor and an illumination sensor can be disposed behind (below) the display panel 110 in another optical area OA. For example, the detection sensor can be an infrared sensor that detects infrared rays.

In this case, by disposing the optical area OA where the detection sensor is disposed on the front surface of the display panel 110, the normal area NA of the display panel 110 can be decreased. As described above, the optical area OA can adopt a pixel density differential design scheme in which the number of subpixels SP per unit area is smaller than that of the normal area NA in order to secure transmittance.

In this case, since the optical area OA has fewer subpixels SP than the normal area NA, image quality such as resolution and luminance can be deteriorated.

Further, a chemical process that reacts with metal can be performed on the transmissive area TA in order not to form a metal layer that interferes with the light reception of the optical electronic device 11 in the transmissive area TA while various metal layers including metal materials are formed in the emission areas EA. For example, the second electrode CE disposed on the transmissive area TA can be removed. However, in such a case, the luminous efficiency can be deteriorated because some metallic materials included in the emission layer EL should be removed.

Therefore, the detection sensor may not be disposed on the lower surface of the substrate, but can be disposed on the optical electronic device 11, which is a light emitting element or a camera. Further, to prevent image quality from deteriorating in the optical area OA, the subpixel can be disposed in the same structure as the normal area NA, and image quality deterioration can be addressed by disposing a transmissive sensor 600 using a transparent material. The display device 100 having such a structure is described with reference to the drawings.

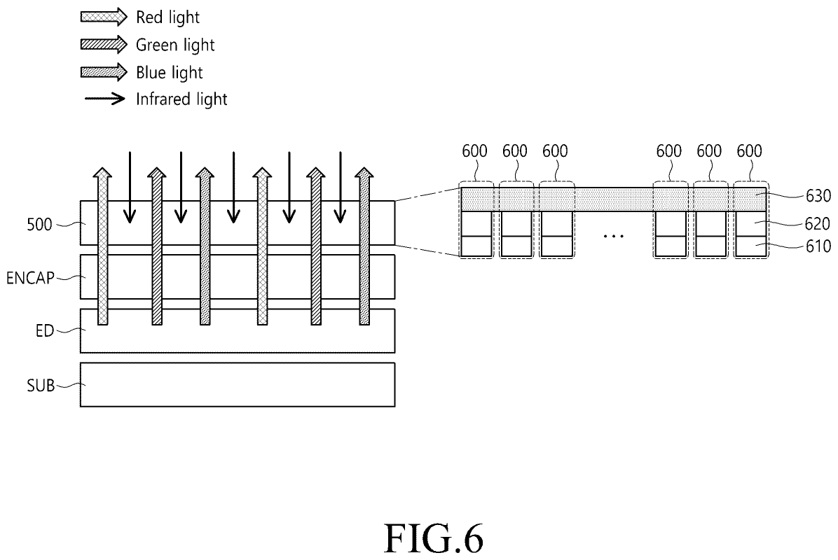

FIG. 6 is a view illustrating that a transmissive sensor 600 is disposed in a display device 100 according to example embodiments of the disclosure.

Referring to FIG. 6, the light emitting element ED can be disposed on the substrate SUB. An encapsulation layer ENCAP can be disposed on the light emitting element ED. A transmissive sensor layer 500 can be disposed on the encapsulation layer ENCAP.

The light emitting element ED can emit light, such as red light, green light, and blue light. In the drawings, it is illustrated that one light emitting element ED emits all of the red light, green light, and blue light, but this is a conceptual view for brief illustration, and in reality, the color that emits light can be determined for each light emitting element ED. For example, the light emitting element ED can emit one or two of the red light, green light, and blue light, without being limited thereto.

As described above, an encapsulation layer ENCAP can be disposed on the light emitting element ED to prevent external moisture or oxygen from penetrating into the light emitting element ED.

A transmissive sensor layer 500 can be disposed on the encapsulation layer. The transmissive sensor layer 500 can be the above-described detection sensor such as a proximity sensor, an illuminance sensor, or the like.

The transmissive sensor layer 500 can include a plurality of transmissive sensors 600. Each of the transmissive sensors 600 can include an anode 610, an active layer 620, and a cathode 630. For example, the active layer 620 can be disposed on the anode 610, and the cathode 630 can be disposed on the active layer 620. The anode 610 and the cathode 630 can include a transparent material or a translucent material. The active layer 620 can include an organic material. As a result, the transmissive sensor 600 can transmit light in a visible light band.

Accordingly, light generated from the light emitting element ED can be emitted to the outside without being blocked.

Further, the active layer 620 of the transmissive sensor 600 can be a photoelectric element that generates a current when receiving light. The band of light where the active layer 620 of the transmissive sensor 600 generates a current in response to external light can be a band such as of infrared light, visible light, or ultraviolet light. Hereinafter, it is assumed that the band of external light to which the active layer 620 of the transmissive sensor 600 reacts is infrared light.

The current generated from the active layer 620 of the transmissive sensor 600 can be sensed from the anode 610 or the cathode 630 of the transmissive sensor 600 to perform a sensing function for external light.

The plurality of transmissive sensors 600 can be disposed in the normal area NA. Further, the plurality of transmissive sensors 600 can be disposed in the optical area OA. The anode 610 and the active layer 620 of the transmissive sensor 600 can be disposed in each of the plurality of transmissive sensors 600 disposed in the optical area OA.

The cathode 630 of the transmissive sensor 600 can be entirely deposited on the optical area OA. Accordingly, the plurality of transmissive sensors 600 can include a structure in which they share an integral cathode 630.

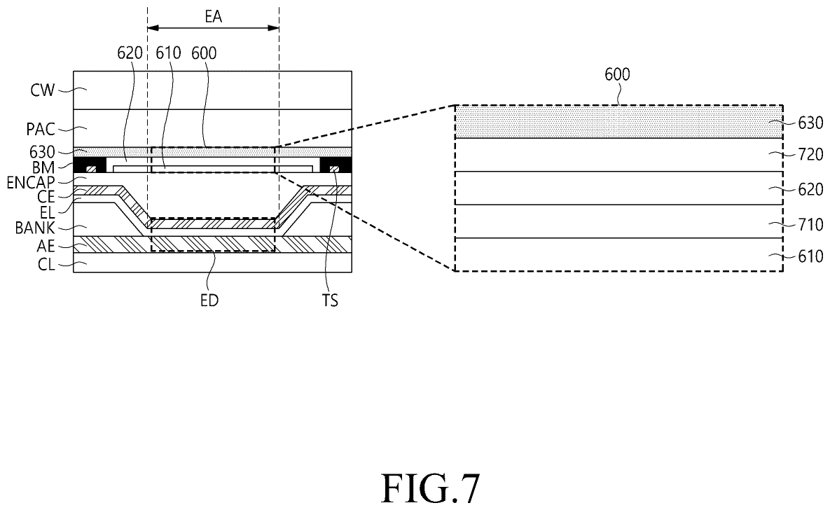

FIG. 7 is a view illustrating a cross-sectional structure in which a transmissive sensor 600 is disposed in an emission area EA according to example embodiments of the disclosure.

The normal area NA can include an emission area EA. Since the optical area OA is also included in the display area DA, the optical area OA can include an emission area EA. Therefore, the cross-sectional structure illustrated in FIG. 7 can be a cross-sectional view in the normal area NA or a cross-sectional view in the optical area OA.

Referring to FIG. 7, a first electrode AE can be disposed on the circuit layer CL. A bank BANK can be disposed on the first electrode AE. In the bank BANK, a portion of an area corresponding to the emission area EA of the subpixel SP can be open. For example, the opening of the bank BANK can correspond to the e emission area EA of the subpixel SP. The light emitting layer EL can be disposed on the side surface of the bank BANK and in the opening of the bank BANK. The second electrode CE can be disposed on the light emitting layer EL. An encapsulation layer ENCAP can be disposed on the second electrode CE. Although the encapsulation layer ENCAP is illustrated to have a single layer structure in FIG. 7, it can have a multi-layer structure including a first encapsulation layer ENCAP, a second encapsulation layer ENCAP, and a third encapsulation layer ENCAP, without being limited thereto.

The touch sensor TS can be disposed on the encapsulation layer ENCAP. The touch sensor TS can include a touch sensor metal TSM and a bridge metal BRG, but for convenience of description, it is illustrated as a single touch sensor TS in FIG. 7. For example, the touch sensor metals TSM can be disposed on the bridge metal BRG, and the bridge metal BRG can be disposed on the encapsulation layer ENCAP The touch sensor TS can also be disposed in the optical area OA, and since the touch sensor TS is a non-transmissive sensor that does not transmit light, it can be disposed not to overlap the emission area EA and the transmissive area TA. Since the touch sensor TS does not overlap the emission area EA, it does not overlap the light emitting element ED. Further, a black matrix BM disposed to cover the touch sensor TS can be disposed on the touch sensor TS.

A transmissive sensor 600 can be disposed in a lateral direction of the black matrix BM to overlap the emission area. For example, the transmissive sensor 600 can comprise the anode 610, the active layer 620 and the cathode 630. Specifically, the anode 610 of the transmissive sensor 600 can be disposed on the encapsulation layer ENCAP of the emission area EA. The active layer 620 can be disposed on the anode 610 of the transmissive sensor 600. The anode 610 and the active layer 620 of the transmissive sensor 600 can be disposed in the lateral direction of the black matrix BM.

The cathode 630 of the transmissive sensor 600 can be disposed on the active layer 620. The cathode 630 can be disposed in an integrated single layer to cover the entire area in which the transmissive sensor 600 is disposed. Therefore, it can also overlap the black matrix BM, and the cathodes 630 of the plurality of transmissive sensors 600 can be integrally disposed.

A protective layer PAC can be disposed on the transmissive sensor 600. For example, protective layer PAC can be disposed on the cathode 630 of the transmissive sensor 600. In other words, the protective layer PAC can be disposed on the touch sensor TS and the transmissive sensor 600.

The transmissive sensor 600 can further include a hole transport layer 710 between the active layer 620 and the anode 610. Further, the transmissive sensor 600 can further include an electron transport layer 720 between the active layer 620 and the cathode 630.

The black matrix BM can be a partition wall disposed between the plurality of transmissive sensors 600 to divide the components. Specifically, the black matrix BM can serve as a pore and wrinkle that is disposed in the lateral direction of the anode 610 and the active layer 620 of the transmissive sensor 600 to divide the plurality of transmissive sensors 600. Therefore, when the plurality of transmissive sensors 600 are disposed, the black matrix BM can be disposed between the anode 610 and the active layer 620 of each transmissive sensor 600.

Meanwhile, according to an embodiment of the disclosure, the transmissive sensor 600 can be disposed according to the color of the light emitted by the subpixel SP, i.e., the wavelength band of light.

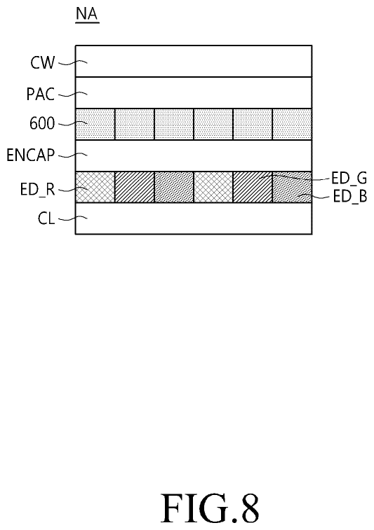

FIG. 8 is a view illustrating that the transmissive sensor 600 is disposed on each of the light emitting elements ED_R, ED_G, and ED_B of the subpixel SP in the normal area NA according to example embodiments of the disclosure.

The light emitting element ED can be disposed on the circuit layer CL. Referring to FIG. 8, a red light emitting element ED_R emitting red light, a green light emitting element ED_G emitting green light, and a blue light emitting element ED_B emitting blue light can be disposed on the circuit layer CL.

Further, as described above with reference to FIG. 7, an encapsulation layer ENCAP can be disposed on the light emitting element ED. Referring to FIG. 8, the encapsulation layer ENCAP can be disposed on the red light emitting element ED_R emitting red light, the green light emitting element ED_G emitting green light, and the blue light emitting element ED_B emitting blue light. The touch sensor TS and the transmissive sensor 600 can be disposed on the encapsulation layer ENCAP. However, for convenience of description, illustration of the touch sensor TS and the black matrix BM on the touch sensor TS is omitted in FIG. 8.

Further, a protective layer PAC can be disposed on the transmissive sensor 600. The cover window CW can be disposed on the protective layer PAC.

Referring to FIG. 8, the transmissive sensor 600 can be disposed on each light emitting element ED in the normal area NA, i.e., the red light emitting element ED_R, the green light emitting element ED_G, and the blue light emitting element ED_B. Since the transmissive sensor 600 is a transparent device that transmits light, even when it is disposed on the light emitting element ED in the normal area NA, the image quality of the emission area EA is not deteriorated.

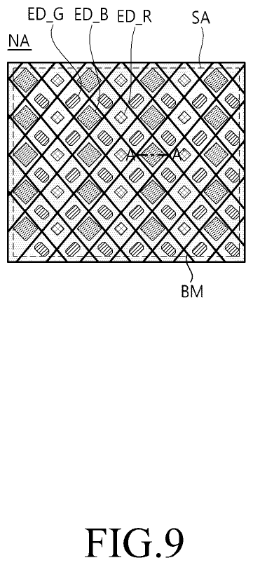

FIG. 9 is a plan view illustrating an example of an area SA in which a transmissive sensor 600 is disposed in a normal area NA of a display panel 110 according to example embodiments of the disclosure.

Particularly, FIG. 9 is a plan view corresponding to a case in which the transmissive sensor 600 is disposed on each of the red light emitting element ED_R, the green light emitting element ED_G, and the blue light emitting element ED_B as illustrated in FIG. 8.

As one example, the transmissive sensor 600 can be disposed on each light emitting element ED in the normal area NA. Referring to FIGS. 9 and 8, the transmissive sensor 600 can be disposed on the red light emitting element ED_R, the green light emitting element ED_G, and the blue light emitting element ED_B disposed in a portion of the normal area NA, without being limited thereto.

On the other hand, since the active layer 620 of the transmissive sensor 600 is an element that senses light of an infrared band wavelength in response to infrared rays received from the outside, the transmissive sensor 600 may not be disposed on the red light emitting element ED_R that emits red light, which has a wavelength close to infrared, to reduce the probability of sensor malfunction. For example, the transmissive sensor 600 can be disposed on the green light emitting element ED_G and the blue light emitting element ED_B disposed in a portion of the normal area NA.

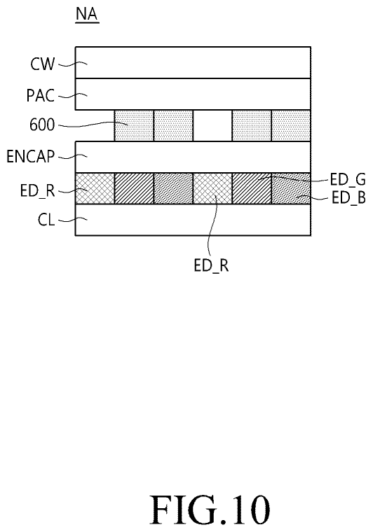

FIG. 10 is a view illustrating that the transmissive sensor 600 according to example embodiments of the disclosure is disposed on the green light emitting element ED_G and the blue light emitting element ED_B of the subpixel SP in the normal area NA.

Referring to FIG. 10, the arrangement of the remaining components except for the transmissive sensor 600 can be the same as that of FIG. 8. The transmissive sensor 600 can be disposed on the green light emitting element ED_G emitting green light and the blue light emitting element ED_B emitting blue light. The transmissive sensor 600 may not be disposed on the red light emitting element ED_R that emits red light.

Through a structure in which the transmissive sensor 600 that senses light in the infrared band is not disposed on the red light emitting element ED_R that emits red light close to the infrared band, it is possible to reduce an error of incorrectly sensing light output from the red light emitting element ED_R as infrared light.

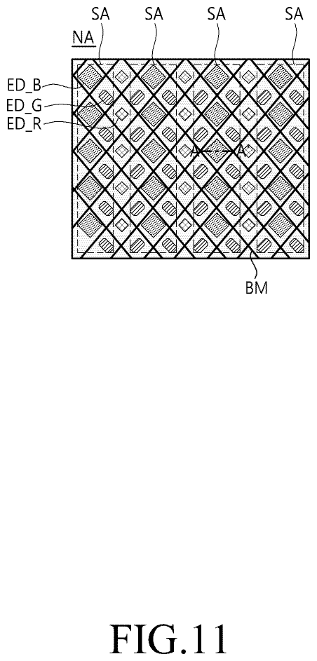

FIG. 11 is a plan view illustrating an example of an area SA in which a transmissive sensor 600 is disposed in a normal area NA of a display panel 110 according to example embodiments of the disclosure.

Referring to FIG. 11, the transmissive sensor 600 can be disposed on the green light emitting element ED_G and the blue light emitting element ED_B except for an area overlapping the red light emitting element ED_R in a portion of the normal area NA. Since the transmissive sensor 600 senses light in the infrared band, it is possible to reduce an error of incorrectly sensing light output from the red light emitting element ED_R as infrared light by not disposing the transmissive sensor 600 on the red light emitting element ED_R that emits red light close to the infrared band.

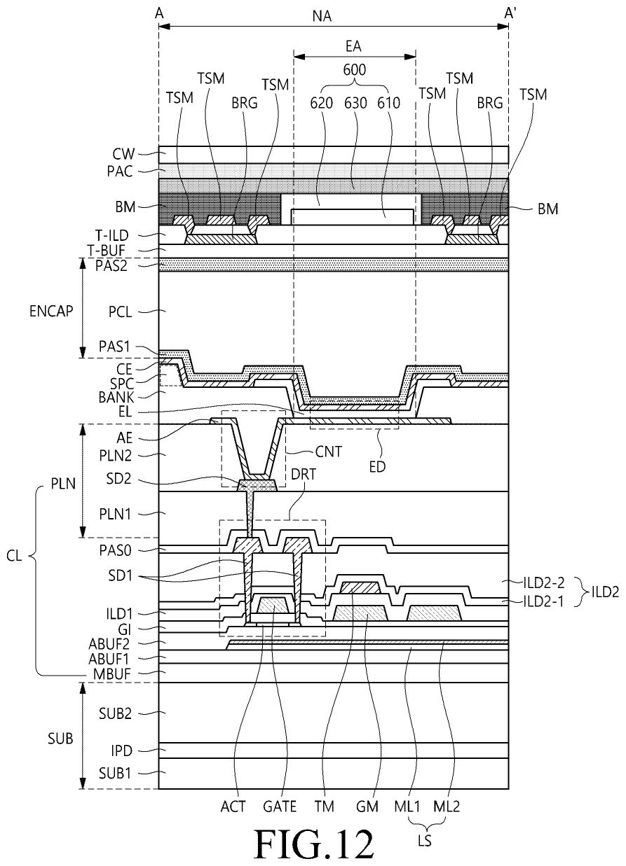

FIG. 12 is a cross-sectional view taken along dashed line A-A′ of FIGS. 9 and 11.

The configuration of FIG. 12 can be identical to that of the normal area NA of FIG. 5 except that the transmissive sensor 600 is disposed.

Referring to FIG. 12, the transmissive sensor 600 can be disposed on the touch interlayer insulation film T-ILD to overlap the emission area EA. Specifically, the anode 610 of the transmissive sensor 600 can be disposed on the touch interlayer insulation film T-ILD. The active layer 620 of the transmissive sensor 600 can be disposed on the anode 610. The cathode 630 of the transmissive sensor 600 can be disposed on the active layer 620.

Meanwhile, a black matrix BM can be disposed in a lateral direction of the anode 610 and the active layer 620. The black matrix BM is disposed on the touch sensor metal TSM. The black matrix BM can be disposed not to overlap the emission area EA. The black matrix BM can serve as a partition wall dividing each of the plurality of transmissive sensors 600. A side surface of the black matrix BM can contact a side surface of the active layer 620.

A cathode 630 can be disposed on the active layer 620 of the transmissive sensor 600. The cathode 630 can be disposed as a single layer. Accordingly, the cathode 630 can be disposed adjacent to the active layer 620, and can also be disposed adjacent to the black matrix BM in contact with the active layer 620.

A protective layer PAC can be disposed on the cathode 630 of the transmissive sensor 600. The cover window CW can be disposed on the protective layer PAC.

As described above, the anode 610 and the cathode 630 of the transmissive sensor 600 can include a transparent material or a translucent material. The active layer 620 of the transmissive sensor 600 can include a transparent material or a translucent material including an organic material.

As a result, even when the transmissive sensor 600 is disposed to overlap the light emitting element ED in the emission area EA, it transmits the light generated by the light emitting element ED. Therefore, even without applying a pixel density differential design scheme or a pixel size differential design scheme to increase transmittance in the area where the detection sensor is disposed, image quality deterioration can be prevented by disposing the transmissive sensor 600, which is a detection sensor, on the emission area EA.

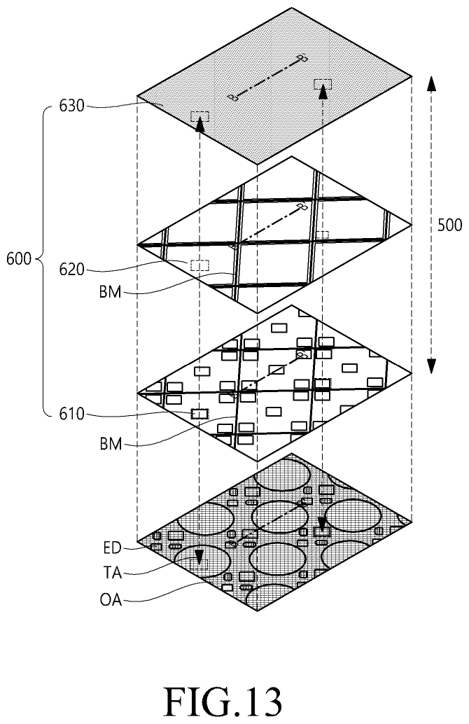

FIG. 13 is a perspective view illustrating an optical area OA in which a light emitting element ED of a subpixel SP, a transmissive area TA, and a transmissive sensor 600 are disposed according to example embodiments of the disclosure.

The perspective view illustrated in FIG. 13 illustrates a structure in which the light emitting element ED and the transmissive sensor 600 in the optical area OA are stacked on the substrate SUB of the display panel 110.

Referring to FIG. 13, a light emitting element ED and a transmissive area TA can be disposed in the optical area OA. The light emitting element ED and the transmissive area TA can have the same structure as the optical area OA of FIG. 4 described above. An optical electronic device 11 can be disposed on a lower surface of the substrate SUB to overlap a plurality of transmissive areas TA. The optical electronic device 11 can be an optical sensor (camera) that senses an image.

The touch sensor TS can be disposed in a lattice pattern so as not to overlap the transmissive area TA and the light emitting element ED. The black matrix BM can be disposed on the touch sensor TS in a lattice pattern so as to overlap the touch sensor TS. The touch sensor TS can be a non-transmissive sensor that does not transmit light.

The anode 610 of the transmissive sensor 600 can be disposed on each light emitting elements ED and transmissive area TA. The anode 610 can be disposed in each transmissive area TA. Further, the anode 610 can be disposed for each light emitting element ED. The anode 610 can include a transparent material or a translucent material to transmit light.

An active layer 620 can be disposed on the anode 610 of the transmissive sensor 600. When the cells are divided based on the lattice of the black matrix BM, the active layer 620 can be disposed for each cell of the black matrix BM in the optical area OA. The active layer 620 can include an organic material.

The anode 610 and the active layer 620 can be positioned in the lateral direction in the same layer as the black matrix BM. For example, the transmissive sensor 600 comprising the anode 610 and the active layer 620 can be disposed between the black matrix BM. The lateral direction of the active layer 620 can contact a lateral direction of the black matrix BM. The active layer 620 can cover the side and top surfaces of the anode 610.

A cathode 630 can be disposed on the active layer 620 of the transmissive sensor 600. The cathode 630 can be disposed as an integrated single layer in the optical area OA, without being limited thereto. Since the cathode 630 is disposed as an integrated single layer on the active layer 620, it can be disposed to overlap the black matrix BM disposed in the optical area OA. The cathode 630 can also be disposed to overlap the transmissive area TA of the optical area OA. Further, the cathode 630 can transmit light, including a transparent material or a translucent material.

As a result, even when the transmissive sensor 600 is disposed to overlap the light emitting element ED in the emission area EA, it transmits light generated by the light emitting element ED. Further, even when the transmissive sensor 600 is disposed on the optical electronic device 11 in the transmissive area TA, it transmits light entering from the outside to the optical electronic device 11.

The transmissive sensor 600 including the anode 610, the active layer 620, and the cathode 630 can be a photoelectric element that generates electricity when receiving light of a specific band. For example, when the active layer 620 receives light in the infrared band, it can generate electricity according to light in the infrared band. The generated electricity can be sensed by the sensing unit through the anode 610 and the cathode 630 adjacent to the active layer 620. For example, the display controller DCTR can perform sensing by functioning as a sensing unit. The display controller DCTR can serve as a sensing unit, such as sensing a distance to an object in front of the display device 100 or measuring illuminance around the display device 100, based on the sensed value.

Therefore, it is possible to reduce the area of the optical area and securing the normal area NA by disposing the transmissive sensor 600 serving as a detection sensor and the optical electronic device 11 serving as an image sensor to overlap each other.

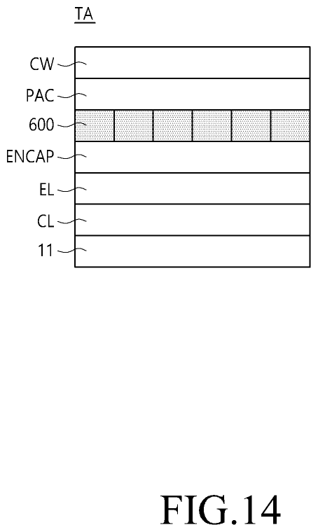

FIG. 14 is a view illustrating that a transmissive sensor 600 is disposed on each light emitting element ED_R, ED_G, and ED_B of the subpixel SP in a transmissive area TA according to example embodiments of the disclosure.

For example, the transmissive sensor 600 can be disposed on each light emitting element ED in the transmissive area TA, i.e., the red light emitting element ED_R, the green light emitting element ED_G, and the blue light emitting element ED_B.

Referring to FIG. 14, a circuit layer CL can be disposed on the optical electronic device 11. Here, the optical electronic device 11 can be a camera (image sensor). Further, the light shield layer LS and material layers (e.g., a metal material layer, a semiconductor layer, etc.) having electrical properties may not be disposed on the circuit layer CL illustrated in FIG. 10.

Although it is illustrated that the light emitting layer EL is disposed on the circuit layer CL, the light emitting layer EL may or may not be disposed on the area in which the optical electronic device 11 is disposed. Further, the first electrode AE and the second electrode CE may not be disposed on the optical electronic device 11. Referring to FIG. 14, it is assumed that the light emitting layer EL is disposed. An encapsulation layer ENCAP can be disposed on the light emitting layer EL. A transmissive sensor 600 can be disposed on the encapsulation layer ENCAP. A protective layer PAC can be disposed on the transmissive sensor 600. The cover window CW can be disposed on the protective layer PAC.

The optical electronic device 11 should receive light from the outside for image sensing, and as described above, layers that interfere with the propagation of light in the first electrode AE, the second electrode CE, and the circuit layer CL may not be disposed on the optical electronic device 11.

Since the transmissive sensor 600 includes a transparent element and transmits light, even when it is disposed on the optical electronic device 11, it may not interfere with the optical electronic device 11 receiving light from the outside. Further, it is possible to secure a wide area in which the normal area NA can be disposed by disposing the transmissive sensor 600 and the optical electronic device 11, which is an image sensor, to overlap each other.

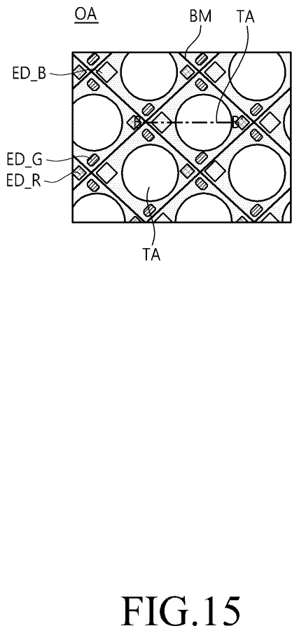

FIG. 15 is a plan view illustrating an optical area OA in which a light emitting element ED and a transmissive area TA are disposed according to example embodiments of the disclosure.

Referring to FIG. 15, light emitting elements ED_R, ED_G and ED_B and a transmissive area TA can be disposed in the optical area OA. The optical area OA illustrated in FIG. 15 can have the same structure as the transmissive area TA illustrated in FIG. 4 except for the transmissive sensor 600. In other words, the second electrode CE may not be disposed in the transmissive area TA. The transmissive area TA can correspond to the opening of the second electrode CE.

Light emitting elements ED_R, ED_G, and ED_B can be disposed in the optical area OA. Further, the transmissive area TA described in connection with FIGS. 4 and 5 can be disposed alternately with the light emitting elements ED_R, ED_G, and ED_B.

Further, a transmissive sensor 600 can be disposed on each of the light emitting element ED and the transmissive area TA disposed in the optical area OA. The transmissive sensor 600 disposed in the optical area OA can transmit light generated by the light emitting element ED and transmit light entering from the outside of the display panel 110 through the transmissive area TA.

The touch sensor TS and the black matrix BM disposed to cover the touch sensor TS can also be disposed in the optical area OA where the transmissive area TA is disposed. The touch sensor TS and the black matrix BM can be disposed in a lattice shape in an area that does not overlap the emission area EA and the transmissive area TA.

The optical electronic device 11 can be disposed in the optical area OA. The optical electronic device 11 can be an optical sensor that receives light transmitted through the transmissive area TA and performs an image sensing function.

Since the optical electronic device 11, which is an optical sensor, is a sensor disposed in the optical area OA, it can be disposed to overlap a portion of the emission area EA of the optical area OA.

Since the transmissive sensor 600 can be disposed on the transmissive area TA, the transmissive sensor 600 and the optical electronic device 11, which is an optical sensor, can be disposed to overlap each other.

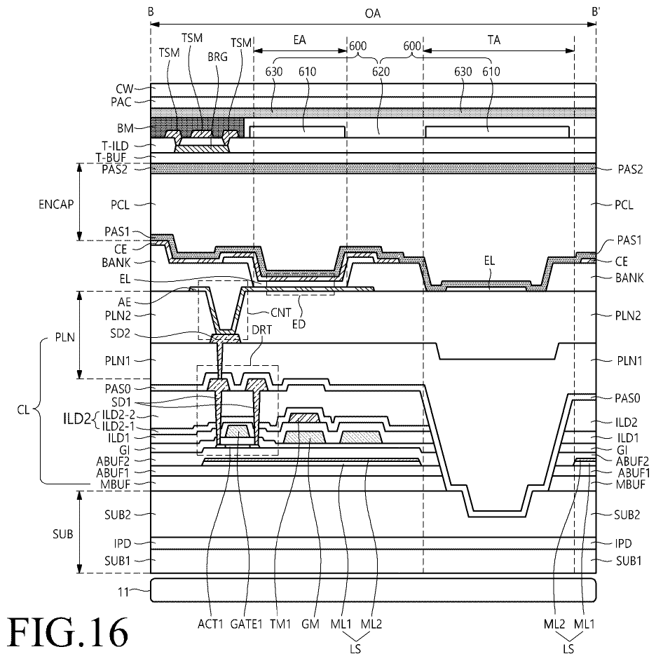

In the cross-sectional view of the components described in connection with FIG. 13 and FIG. 15, taken along dashed line B-B′, the structure is identical to that of FIG. 16.

FIG. 16 is a cross-sectional view taken along dashed line B-B′ of FIGS. 13 and 15 in an optical area OA in which a subpixel SP, a transmissive area TA, and a transmissive sensor 600 are disposed according to example embodiments of the disclosure.

Referring to FIG. 16, the remaining components except for the black matrix BM and the transmissive sensor 600 on the touch sensor TS can be the same as the normal area NA and the optical area OA of FIG. 5, and can include all of the components of FIG. 13.

A light emitting element ED can be disposed in the emission area EA of the optical area OA.

In the transmissive area TA of the optical area OA, the metal material layers ML1, ML2, GATE1, GM, TM1, SD1, and SD2 and the semiconductor layer ACT may not be disposed in the transmissive area TA so as to receive light through the optical electronic device 11 disposed on the lower surface of the substrate. Such a configuration of the transmissive area TA can be referred to as a transmission hole, and the transmission hole can be formed to overlap the transmissive area TA.

The optical electronic device 11 disposed on the lower surface of the substrate can be an optical sensor (camera) that senses an image, as described in connection with FIG. 13. The optical electronic device 11 can be disposed over the entire optical area OA. In other words, it can be disposed to overlap the emission area EA and the transmissive area TA of the optical area OA.

A black matrix BM can be disposed to cover the touch sensor TS in the optical area OA. In the cross section taken along dashed line B-B′, the touch sensor TS can be disposed far from the transmissive area TA with respect to the emission area EA. Since the black matrix BM is disposed to cover the touch sensor TS, it may not overlap the emission area EA and the transmissive area TA. The touch sensor TS can be a non-transmissive sensor that does not transmit light.

For example, the transmissive sensor 600 can comprise the anode 610, the active layer 620 and the cathode 630. The anode 610 of the transmissive sensor 600 can be disposed on the light emitting element ED to overlap the emission area EA. Further, the anode 610 can be disposed to overlap the transmissive area TA. The anode 610 can include a transparent material or a translucent material to transmit light.

An active layer 620 can be disposed on the anode 610 of the transmissive sensor 600. The active layer 620 can cover the side and top surfaces of the anode 610 of the transmissive sensor 600. In the optical area OA, the active layer 620 of the transmissive sensor 600 can be disposed in all of the areas other than the area in which the black matrix BM is disposed. The anode 610 and the active layer 620 of the transmissive sensor 600 can be positioned in the lateral direction in the same layer as the black matrix BM, and the side surface of the active layer 620 can contact the side surface of the black matrix BM. For example, the lateral direction of the active layer 620 can contact a lateral direction of the black matrix BM. The active layer 620 can include an organic material.

A cathode 630 can be disposed on the active layer 620 of the transmissive sensor 600. The cathode 630 can be disposed as an integrated single layer in the optical area OA, without being limited thereto. Therefore, it can be disposed to overlap the black matrix BM disposed in the optical area OA. Since the cathode 630 is disposed in the optical area OA, the cathode 630 can also overlap the emission area EA and the transmissive area TA. Further, the cathode 630 can transmit light, including a transparent material or a translucent material.

A protective layer PAC can be disposed on the cathode 630 of the transmissive sensor 600. The cover window CW can be disposed on the protective layer PAC.

As a result, even when the transmissive sensor 600 is disposed to overlap the light emitting element ED in the emission area EA, it transmits light generated by the light emitting element ED. Further, even when it is disposed on the optical electronic device 11 on the transmission hole in the transmissive area TA, it transmits light entering from the outside to the optical electronic device 11.

Therefore, as described in connection with FIGS. 13 to 15, it is possible to decrease the physical area of the optical area and secure the normal area NA by overlapping the transmissive sensor 600 serving as a detection sensor and the optical electronic device 11 serving as an image sensor.

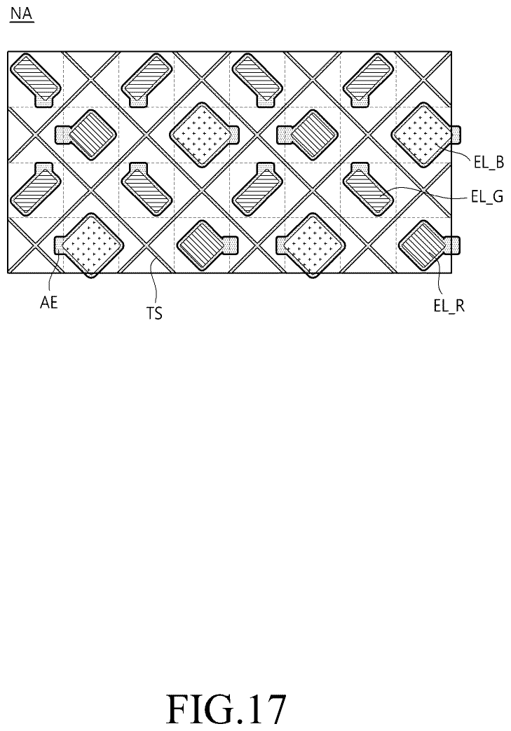

FIGS. 17, 18, 19, and 20 are views illustrating a process of disposing a transmissive sensor 600 on an optical area OA of a display panel 110 according to example embodiments of the disclosure.

Referring to FIG. 17, the first electrode AE and the light emitting layer EL of the light emitting element ED can be disposed on the optical area OA. Further, the second electrode CE and the encapsulation layer ENCAP of the light emitting element ED can be further disposed on the first electrode AE and the light emitting layer EL of the light emitting element ED, but they are omitted from the illustration for convenience of description.

A touch sensor TS can be disposed in the optical area OA. The touch sensor TS can be disposed in a lattice shape so as not to overlap the first electrode AE and the light emitting layer EL of the light emitting element ED. Further, a touch buffer film T-BUF and a touch interlayer insulation film T-ILD can be disposed on the encapsulation layer ENCAP, but they are omitted from the illustration in the drawings for convenience of description.

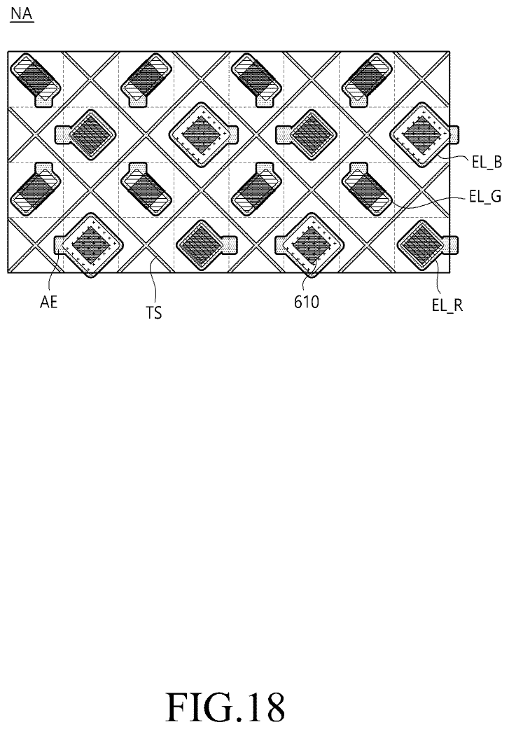

Referring to FIG. 18 together with FIG. 17, the anode 610 of the transmissive sensor 600 can be disposed to overlap the first electrode AE and the light emitting layer EL of the light emitting element ED. Although the drawings illustrate that the anode 610 of the transmissive sensor 600 is disposed on each of the red light emitting layer EL, the green light emitting layer EL, and the blue light emitting layer EL, it may not be disposed on the red light emitting layer EL.

Through a structure in which the transmissive sensor 600 that senses light in the infrared band is not disposed on the red light emitting layer EL that emits red light close to the infrared band, it is possible to reduce an error of incorrectly sensing light output from the red light emitting element ED_R as infrared light.

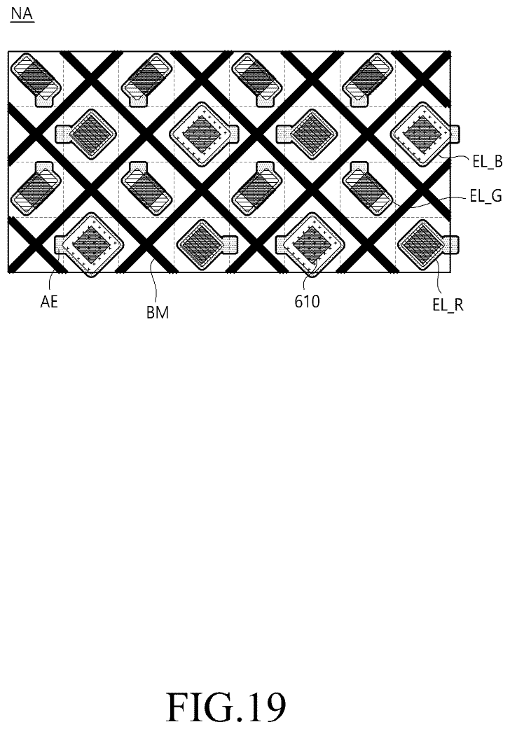

Referring to FIG. 19 together with FIG. 18, the black matrix BM can be disposed to cover the touch sensor TS. The black matrix BM can be disposed in a lattice shape in an area other than the emission area EA where the light emitting element ED is disposed along the touch sensor TS. Referring to FIGS. 18 and 19, it is illustrated that the black matrix BM on the touch sensor TS is disposed after the anode 610 of the transmissive sensor 600 is disposed, but the arrangement order of the anode 610 and the touch sensor TS can vary according to the manufacturing process of the display panel 110.

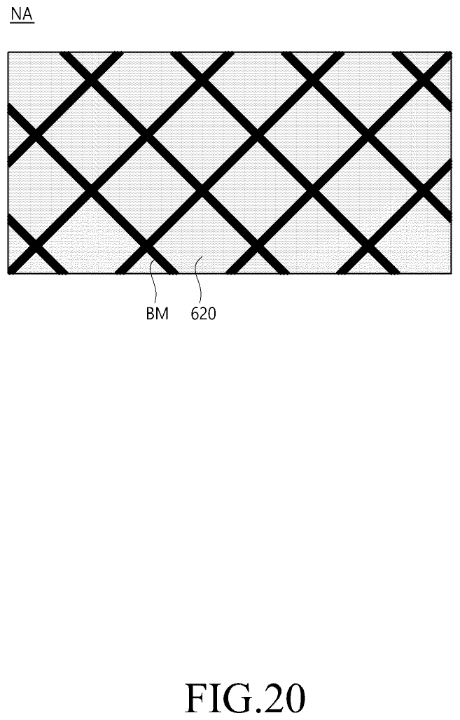

Referring to FIG. 20 together with FIG. 19, an active layer 620 can be disposed on the anode 610 of the transmissive sensor 600. The active layer 620 can be disposed in an area other than an area where the black matrix BM is disposed in the optical area OA. In other words, the active layer 620 can be disposed to overlap the emission area EA in the optical area OA. The anode 610 and the active layer 620 of the transmissive sensor 600 can be positioned in the lateral direction in the same layer as the black matrix BM. The side surface of the active layer 620 can be disposed to contact the side surface of the black matrix BM. For example, the lateral direction of the active layer 620 can contact a lateral direction of the black matrix BM.

Referring to FIG. 20, a cathode 630 can be disposed on the active layer 620 and the black matrix BM. For example, the cathode 630 can be disposed to overlap the black matrix BM. The cathode 630 can be disposed as an integrated single layer in the optical area OA, without being limited thereto. Accordingly, the cathode 630 can be disposed to overlap the emission area EA as well.

The transmissive sensor 600 can include the above-described anode 610, active layer 620, and cathode 630, and can include a transparent element to transmit light. For example, the cathode 630 can transmit light, including a transparent material or a translucent material. Accordingly, light generated from the light emitting element ED disposed in the optical area OA can be transmitted.

Meanwhile, a circuit for driving the transmissive sensor 600 can be configured in the display device 100.

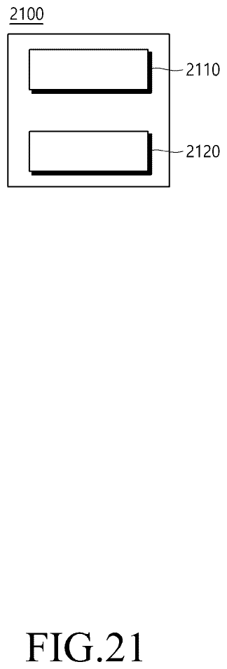

FIG. 21 is a view illustrating a configuration of a transmissive sensor detection circuit 2100 according to example embodiments of the disclosure.

Referring to FIG. 21, the transmissive sensor detection circuit 2100 can include a driving unit 2110 and a detection unit 2120. The transmissive sensor detection circuit 2100 can be disposed in the display device 100. For example, the transmissive sensor detection circuit 2100 can be a component included in the display controller DCTR illustrated in FIG. 2. Alternatively, it can be a component disposed separately from the display controller DCTR.

The driving unit 2110 can drive the first anode 610 and the first cathode 630 of the first transmissive sensor 600, which is one of the plurality of transmissive sensors 600 disposed on the display panel 110.

For example, a first signal can be applied to the first anode 610 and a second signal can be applied to the first cathode 630. For example, the first signal can be a signal having a varying voltage level, and the second signal can be a signal having a constant voltage level. As another example, the first signal can be a signal having a constant voltage level, and the second signal can be a signal having a varying voltage level.

The detection unit 2120 can detect a change (e.g., a change in current) in an electrical signal through one of the first anode 610 and the first cathode 630 of the first transmission sensor 600.

The driving unit 2110 and the detection unit 2120 can be integrated or configured separately.

At least one of the driving unit 2110 and the detection unit 2120 can be a component included in the touch sensing circuit or in the display controller DCTR.

Example embodiments of the disclosure described above are briefly described below.

A display device according to aspects of the disclosure can comprise a substrate including a display area including a plurality of emission areas and a non-display area outside the display area, a plurality of light emitting elements disposed on the substrate and respectively positioned in the plurality of emission areas, and a transmissive sensor layer disposed on the plurality of light emitting elements. The plurality of light emitting elements include a first light emitting element. The transmissive sensor layer can be disposed on the first light emitting element and include a first transmissive sensor overlapping the first light emitting element.

The first transmissive sensor includes a first anode disposed on the first light emitting element, a first active layer on the first anode, and a first cathode on the first active layer.

The first active layer can include an organic material.

Each of the first anode and the first cathode can include a transparent material or a translucent material.

The plurality of light emitting elements can include a second light emitting element. The transmissive sensor layer can be disposed on the second light emitting element and can further include a second transmissive sensor overlapping the second light emitting element. The second transmissive sensor can include a second anode disposed on the second light emitting element, a second active layer on the second anode, and a second cathode on the second active layer. The first cathode and the second cathode can be integrated with each other.

The display device can further comprise an encapsulation layer on the plurality of light emitting elements and a non-transmissive sensor disposed on the encapsulation layer. The non-transmissive sensor may not overlap the first light emitting element.

The first transmissive sensor can be positioned in a lateral direction of the non-transmissive sensor.

The display device can further comprise a protective layer disposed on the first transmissive sensor and the non-transmissive sensor.

The display device can further comprise a partition wall disposed between a first anode and a first active layer of the first transmissive sensor and a second anode and a second active layer of the second transmissive sensor.

The partition wall can be disposed on the non-transmissive sensor.

The first light emitting element can emit light of a first color, and the second light emitting element emits light of a second color. The plurality of light emitting elements can further include a third light emitting element emitting light of a third color different from the first color and the second color. The transmissive sensor layer can have no transmissive sensor in an area overlapping the third light emitting element.

The third light emitting element can emit red light.

A difference between a wavelength of the light of the third color and a wavelength of light detected by the first transmissive sensor can be smaller than a difference between a wavelength of the light of the first color and the wavelength of the light detected by the first transmissive sensor, and can be smaller than a difference between a wavelength of the light of the second color and the wavelength of the light detected by the first transmissive sensor.

The substrate can further include a plurality of transmissive areas not overlapping the plurality of emission areas. The display device can further comprise an optical sensor disposed to overlap some of the plurality of emission areas and the plurality of transmissive areas. The transmissive sensor layer can further include at least one first transmissive sensor overlapping the optical sensor.

The first transmissive sensor may not overlap the plurality of light emitting elements and can overlap the transmissive area.

The display device can further comprise an encapsulation layer on the plurality of light emitting elements and a non-transmissive sensor disposed on the encapsulation layer. The non-transmissive sensor may not overlap the first light emitting element and the first transmissive sensor.

The plurality of light emitting elements can include a first electrode disposed in each of the plurality of light emitting elements and a second electrode integrally disposed on the first electrode. The second electrode can form a transmission hole in the plurality of transmissive areas.

The transmission hole can overlap the third transmissive sensor and the optical sensor.

A display device according to aspects of the disclosure can comprise a substrate including a display area displaying an image, the display area including a normal area and an optical area, an optical sensor disposed under the substrate and disposed to overlap the optical area, and at least one transmissive sensor disposed on the substrate and overlapping the optical sensor.

The optical area can further include a plurality of emission areas and a plurality of transmissive areas. A plurality of light emitting elements can be disposed in the plurality of emission areas, respectively. A plurality of transmission holes can be formed in the plurality of transmissive areas. The at least one transmissive sensor can overlap each of at least one of the plurality of transmission holes and at least one of the plurality of emission areas.

The optical sensor can be disposed to overlap one or more of each of the plurality of transmissive sensors and each of the plurality of light emitting elements.

The transmissive sensor can perform a predefined operation using light of a first wavelength transmitted through the optical area. The optical sensor can perform a predefined operation using light of a second wavelength different from the first wavelength, transmitted through the optical area.

A display device according to aspects of the disclosure can comprise a substrate including a display area; a plurality of light emitting elements disposed in the display area on the substrate and including a first light emitting element; and a transmissive sensor layer disposed on plurality of light emitting elements and comprising a plurality of transmissive sensors, wherein the first light emitting element and a first transmissive sensor of the plurality of transmissive sensors overlap each other.

A display device according to aspects of the disclosure can comprise a substrate including a display area displaying an image, the display area including a normal area and an optical area; an optical sensor disposed under the substrate and disposed to overlap the optical area; a plurality of light emitting elements disposed on the normal area and the optical area; at least one transmissive sensor disposed on the plurality of light emitting elements overlapping the optical sensor.

A display device according to aspects of the disclosure can comprise a substrate including a display area displaying an image, the display area including a normal area and an optical area; an optical sensor disposed under the substrate and disposed to overlap the optical area; at least one transmissive sensor overlapping the optical sensor, wherein the number of subpixels per unit area in the optical area is smaller than the number of subpixels per unit area in the normal area, and wherein the transmissive sensor is made of a transparent material.

According to example embodiments of the disclosure described above, there can be provided a display device having a sensor that senses light of a predefined wavelength band (e.g., an infrared band).

According to example embodiments of the disclosure, there can be provided a display device having a transmissive sensor through which light is transmitted.

According to example embodiments of the disclosure, as the sensor receiving light is disposed in the display area of the display panel, and the sensor is configured as a transmissive sensor, the arrangement of the subpixels in the display area of the display panel may not be affected.

According to example embodiments of the disclosure, as the sensor is configured as a transmissive sensor, the resolution and image quality of the display panel may not be deteriorated although the sensor receiving light is disposed in the display area of the display panel.

According to example embodiments of the disclosure, as the camera and the sensor are disposed to vertically overlap each other, the deterioration of the resolution and image quality of the display panel due to the camera and the sensor can be reduced although the camera and the sensor overlap the display area of the display panel.

According to example embodiments of the disclosure, as a sensor having a light-based detection function is configured as a transmissive sensor, the sensor can be disposed to overlap the light emitting element of at least one subpixel. Thus, it is possible to expand the area where the subpixels including light emitting elements are disposed. Therefore, there can be provided a display device with enhanced light emission efficiency to provide a light emission characteristic at reduced power.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

What is claimed is:

1. A display device, comprising:
a substrate including a display area;
a plurality of light emitting elements disposed in the display area on the substrate and including a first light emitting element; and
a transmissive sensor layer disposed on the plurality of light emitting elements and including a plurality of transmissive sensors,
wherein the first light emitting element and a first transmissive sensor of the plurality of transmissive sensors overlap each other.

2. The display device of claim 1, further comprising:
an encapsulation layer disposed on the first light emitting element; and
a cover window disposed on the encapsulation layer,
wherein the transmissive sensor layer is disposed between the encapsulation layer and the cover window.

3. The display device of claim 2, wherein the first transmissive sensor includes:
a first anode disposed on the first light emitting element;
a first active layer on the first anode; and
a first cathode on the first active layer,
wherein the first active layer includes an organic material, and
wherein each of the first anode and the first cathode includes a transparent material or a translucent material.

4. The display device of claim 3, wherein the plurality of light emitting elements further include a second light emitting element,
wherein the transmissive sensor layer is disposed on the second light emitting element and further includes a second transmissive sensor overlapping the second light emitting element,
wherein the second transmissive sensor includes:
a second anode disposed on the second light emitting element;
a second active layer on the second anode; and
a second cathode on the second active layer, and
wherein the first cathode and the second cathode are integrated with each other.

5. The display device of claim 3, further comprising a non-transmissive sensor disposed on the encapsulation layer,
wherein the non-transmissive sensor does not overlap the first light emitting element, and
wherein the first transmissive sensor is positioned in a lateral direction of the non-transmissive sensor.

6. The display device of claim 4, further comprising:
a partition wall disposed between the first anode and the first active layer of the first transmissive sensor and the second anode and the second active layer of the second transmissive sensor; and
a non-transmissive sensor disposed on the encapsulation layer,
wherein the non-transmissive sensor does not overlap the first light emitting element and the second light emitting element, and
wherein the partition wall is disposed on the non-transmissive sensor.

7. The display device of claim 4, wherein the first light emitting element is configured to emit light of a first color, and the second light emitting element is configured to emit light of a second color,
wherein the plurality of light emitting elements further include a third light emitting element configured to emit light of a third color different from the first color and the second color, and
wherein the transmissive sensor layer has no transmissive sensor in an area overlapping the third light emitting element.

8. The display device of claim 7, wherein a difference between a wavelength of the light of the third color and a wavelength of light detected by the first transmissive sensor is smaller than a difference between a wavelength of the light of the first color and the wavelength of the light detected by the first transmissive sensor, and is smaller than a difference between a wavelength of the light of the second color and the wavelength of the light detected by the first transmissive sensor.

9. The display device of claim 1, wherein the display area includes a normal area including a plurality of emission areas, and an optical area including a plurality of emission areas and a plurality of transmissive areas, and
wherein the first transmissive sensor is disposed in the normal area.

10. The display device of claim 9, wherein the plurality of transmissive sensors are disposed on each light emitting element in the normal area, and the plurality of transmissive sensors are transparent devices configured to transmit light.

11. The display device of claim 9, wherein the plurality of transmissive sensors are disposed on the first light emitting element and a second light emitting element of the plurality of light emitting elements in the normal area, and are not disposed on a third light emitting element of the plurality of light emitting elements.

12. The display device of claim 2, wherein the display area includes a normal area including a plurality of emission areas, and an optical area including a plurality of emission areas and a plurality of transmissive areas, and
wherein the first transmissive sensor is disposed in the optical area.

13. The display device of claim 12, further comprising an optical sensor disposed under the substrate and overlapping the optical area,
wherein the optical sensor overlaps the first transmissive sensor.

14. The display device of claim 12, wherein the first transmissive sensor is disposed in one of the plurality of transmissive areas.

15. The display device of claim 12, wherein the first transmissive sensor is disposed in a first emission area among the plurality of emission areas and overlaps the first light emitting element in the first emission area.

16. The display device of claim 12, further comprising a non-transmissive sensor disposed on the encapsulation layer,
wherein the non-transmissive sensor does not overlap the first light emitting element and the first transmissive sensor.

17. The display device of claim 13, wherein the plurality of light emitting elements include a first electrode disposed in each of the plurality of light emitting elements and a second electrode integrally disposed on the first electrode,
wherein the second electrode forms a transmission hole in the plurality of transmissive areas, and
wherein the transmission hole overlaps the first transmissive sensor and the optical sensor.

18. A display device, comprising:
a substrate including a display area configured to display an image, the display area including a normal area and an optical area;
an optical sensor disposed under the substrate and disposed to overlap the optical area;
a plurality of light emitting elements disposed on the normal area and the optical area; and
at least one transmissive sensor disposed on the plurality of light emitting elements and overlapping the optical sensor.

19. The display device of claim 18, wherein the optical area further includes a plurality of emission areas and a plurality of transmissive areas,
wherein the plurality of light emitting elements are disposed in the plurality of emission areas, respectively,
wherein a plurality of transmission holes are formed in the plurality of transmissive areas, and
wherein the at least one transmissive sensor overlaps each of at least one of the plurality of transmission holes and at least one of the plurality of emission areas.

20. The display device of claim 19, wherein the at least one transmissive sensor performs a predefined operation using light of a first wavelength transmitted through the optical area, and
wherein the optical sensor performs a predefined operation using light of a second wavelength different from the first wavelength, transmitted through the optical area.
